(19) United States
(12) Patent Application Publication
(10) Pub. No.: US 2026/0051346 A1
(43) Pub. Date: Feb. 19, 2026

(54) VARIABLE RESISTANCE MEMORY DEVICE

(71) Applicant: Samsung Electronics Co., Ltd., Suwon-si (KR)

(72) Inventors: Kilho LEE, Suwon-si (KR); Daeshik KIM, Suwon-si (KR); Yongjae KIM, Suwon-si (KR)

(73) Assignee: Samsung Electronics Co., Ltd., Suwon-si (KR)

(21) Appl. No.: 19/216,899

(22) Filed: May 23, 2025

(30) Foreign Application Priority Data
Aug. 14, 2024 (KR) 10-2024-0108970

(51) Int. Cl. G11C 11/16; G11C 5/06; H10N 50/10; H10N 50/85

(52) U.S. Cl. CPC G11C 11/1673; G11C 5/063; G11C 11/161; G11C 11/1675; H10N 50/10; H10N 50/85

(57) ABSTRACT

A variable resistance memory device includes a memory cell region including a main cell region, a dummy cell region, a reference wiring region, and a word line strap region. The memory cell region includes word lines extending in a first direction. The main cell region includes bit lines extending in a second direction and memory cells including a real magnetic tunnel junction (MTJ) layer. The dummy cell region includes dummy bit lines extending in the second direction to be equal to the bit lines and dummy memory cells including a dummy MTJ layer. The word line strap region includes word line strap patterns disposed apart from one another in the second direction. The dummy cell region and the reference wiring region include reference wiring lines used as a reference resistor in a read operation of the memory cells, and the reference wiring lines is the dummy bit lines.

### CROSS-REFERENCE TO RELATED APPLICATION

This application is based on and claims priority under 35 U.S.C. § 119 to Korean Patent Application No. 10-2024-0108970, filed on Aug. 14, 2024, in the Korean Intellectual Property Office, the disclosure of which is incorporated by reference herein in its entirety.

### BACKGROUND

The inventive concepts relate to a variable resistance memory device, and more particularly, to a variable resistance memory device configured to enhance a read margin.

Memory devices used in semiconductor products need to increase an operation speed and increase the degree of integration. To satisfy such needs, variable resistance memory devices have been proposed. Variable resistance memory devices may use a current transfer characteristic of a variable resistance layer based on an applied voltage. Representative examples of variable resistance memory devices may include magnetic random access memory (MRAM).

### SUMMARY

The inventive concepts provide to a variable resistance memory device which may enhance a read margin.

A variable resistance memory device according to at least one embodiment includes a memory cell region including a main cell region, a dummy cell region, a reference wiring region, and a word line strap region.

The memory cell region may include a plurality of word lines extending in a first direction and spaced apart from one another in a second direction perpendicular to the first direction a plurality of bit lines on the plurality of word lines, the plurality of bit lines extending in the second direction and spaced apart from one another in the first direction, and a plurality of memory cells each including a real magnetic tunnel junction (MTJ) layer in a first intersection region between one of the plurality of word lines and a corresponding one of the plurality of bit lines.

The dummy cell region may include a plurality of dummy bit lines on the plurality of word lines and extending in the second direction such that at least one of a resistance or capacitance of the plurality of dummy bit lines is equal to the plurality of bit lines, and a plurality of dummy memory cells each including a dummy MTJ layer in a second intersection region between one of the plurality of word lines and a corresponding dummy bit line of the plurality of dummy bit lines.

The word line strap region may include a plurality of word line strap patterns spaced apart from one another in the second direction. The dummy cell region and the reference wiring region may include a plurality of reference wiring lines configured as a reference resistor in a read operation of the plurality of memory cells, and the plurality of reference wiring lines may include the plurality of dummy bit lines.

A variable resistance memory device according to at least one embodiment includes a memory cell region and a core/peripheral circuit region at a perimeter of the memory cell region.

The memory cell region may include a cell center region, a cell edge region at an edge portion of the cell center region, a dummy cell region adjacent to the main cell region, and a word line strap region adjacent to the dummy cell region.

The memory cell region includes a plurality of word lines extending in a first direction and spaced apart from one another in a second direction perpendicular to the first direction, a plurality of bit lines extending in the second direction on the plurality of word lines and spaced apart from one another in the first direction, and a plurality of memory cells each including a real magnetic tunnel junction (MTJ) layer in a first intersection region between one of the plurality of word lines and a corresponding one of the plurality of bit lines.

The dummy cell region may include a plurality of dummy bit lines on the plurality of word lines and extending in the second direction such that at least one of a resistance or capacitance of the plurality of dummy bit lines is equal to the plurality of bit lines, and a plurality of dummy memory cells each including a dummy MTJ layer in a second intersection region between one of the plurality of word lines and a corresponding one of the plurality of bit lines.

The word line strap region may include a plurality of word line strap patterns spaced apart from one another in the second direction. The dummy cell region may be a reference wiring region configured to be used as a reference resistor in a read operation of the plurality of memory cells.

The reference wiring region may include reference wiring lines, the reference wiring lines including the plurality of dummy bit lines configured as the reference resistor. The reference wiring lines may be connected to cell via patterns configuring the plurality of word line strap patterns in at least one of the cell center region and the cell edge region.

A variable resistance memory device according to at least one embodiment includes a memory cell region and a core/peripheral circuit region at a perimeter of the memory cell region. The memory cell region may include a main cell region and a reference wiring region. The main cell region and the reference wiring region may include a plurality of word lines extending in a first direction and spaced apart from one another in a second direction perpendicular to the first direction.

The main cell region may further include a plurality of bit lines on the plurality of word lines, extending in the second direction, and spaced apart from one another in the first direction, and a plurality of memory cells each including a real magnetic tunnel junction (MTJ) layer in an intersection region between one of the plurality of word lines and a corresponding one of the plurality of bit lines.

The reference wiring region may include a reference wiring line, the reference wiring line including one of the plurality of bit lines configured as a reference resistor in a read operation of the plurality of memory cells. The reference wiring line may extend to the core/peripheral circuit region in the second direction.

### BRIEF DESCRIPTION OF THE DRAWINGS

Embodiments will be more clearly understood from the following detailed description taken in conjunction with the accompanying drawings in which:

FIG. 1 is a block diagram illustrating a variable resistance memory device according to at least one embodiment;

FIG. 2 is a circuit diagram illustrating a memory cell array of the variable resistance memory device of FIG. 1;

FIG. 3 is a circuit diagram illustrating a memory cell of FIG. 2;

FIG. 4 is a perspective view illustrating the memory cell of FIG. 2;

FIGS. 5 and 6 are diagrams to describe a read operation of a magnetic tunnel junction (MTJ) layer of the memory cell of FIG. 2;

FIG. 7 is a circuit diagram to describe a read operation of an MTJ layer of the memory cell of FIG. 2;

FIGS. 8 and 9 are diagrams to describe a write operation of an MTJ layer of the memory cell of FIG. 2;

FIG. 10 is an enlarged plan view to describe a variable resistance memory device according to at least one embodiment;

FIG. 11 is an enlarged plan view to describe a memory cell region of a variable resistance memory device according to at least one embodiment;

FIG. 12A is a main cross-sectional view in a word line direction and a bit line direction of FIG. 11;

FIG. 12B is a partial enlarged view of FIG. 12A;

FIG. 13 is a main cross-sectional view in the word line direction of FIG. 11;

FIG. 14 is an enlarged plan view to describe a memory cell region of a variable resistance memory device according to at least one embodiment;

FIG. 15 is a main cross-sectional view in a bit line direction of FIG. 14;

FIG. 16 is a main cross-sectional view in a word line direction of FIG. 14;

FIG. 17 is an enlarged plan view to describe a memory cell region of a variable resistance memory device according to at least one embodiment;

FIG. 18 is a main cross-sectional view in a word line direction and a bit line direction of FIG. 17;

FIG. 19 is a main cross-sectional view in the word line direction of FIG. 17;

FIG. 20 is an enlarged plan view to describe a memory cell region of a variable resistance memory device according to at least one embodiment;

FIG. 21 is a main cross-sectional view in a word line direction and a bit line direction of FIG. 20;

FIG. 22 is a main cross-sectional view in the word line direction of FIG. 20;

FIG. 23 is an enlarged plan view to describe a memory cell region of a variable resistance memory device according to at least one embodiment;

FIG. 24 is a main cross-sectional view in the bit line direction of FIG. 23;

FIG. 25 is a main cross-sectional view in the word line direction of FIG. 23;

FIG. 26 is an enlarged plan view to describe a memory cell region of a variable resistance memory device according to at least one embodiment;

FIG. 27 is a main cross-sectional view in the bit line direction of FIG. 26;

FIG. 28 is a configuration diagram of a data processing system including a variable resistance memory device according to at least one embodiment; and

FIG. 29 is a configuration diagram of a data processing system including a variable resistance memory device according to at least one embodiment.

### DETAILED DESCRIPTION OF THE EMBODIMENTS

Hereinafter, embodiments will be described in detail with reference to the accompanying drawings. Throughout the drawings, like reference numerals indicate like elements, and redundant descriptions thereof are omitted. In addition, embodiments to be described below are only examples, and various modifications from such embodiments may be possible. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. The following embodiments may be implemented as example embodiments, and the following embodiments may also be implemented by a combination of one or more embodiments. Therefore, it should not be construed that the inventive concepts are limited to only one embodiment.

The term “above” and similar directional terms are intended to encompass different orientations of the device in use or operation in addition to the orientation depicted in the figures, and that the device may be otherwise oriented (rotated 90 degrees or at other orientations) and the spatially relative terms used herein interpreted accordingly.

Also, in the specification, the functional elements, including those including terms such as “unit,” “block,” “ . . . controller,” etc. denote units that process at least one function or operation, and may be realized by and/or include processing circuitry such as hardware, software, or a combination of hardware and software unless the context clearly indicates otherwise. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components (such as transistors, resistors, capacitors, etc.) and/or electronic circuits including said components. Connections or connection members of lines between components shown in the drawings illustrate functional connections and/or physical or circuit connections, and the connections or connection members can be represented by replaceable or additional various functional connections, physical connections, or circuit connections in an actual apparatus.

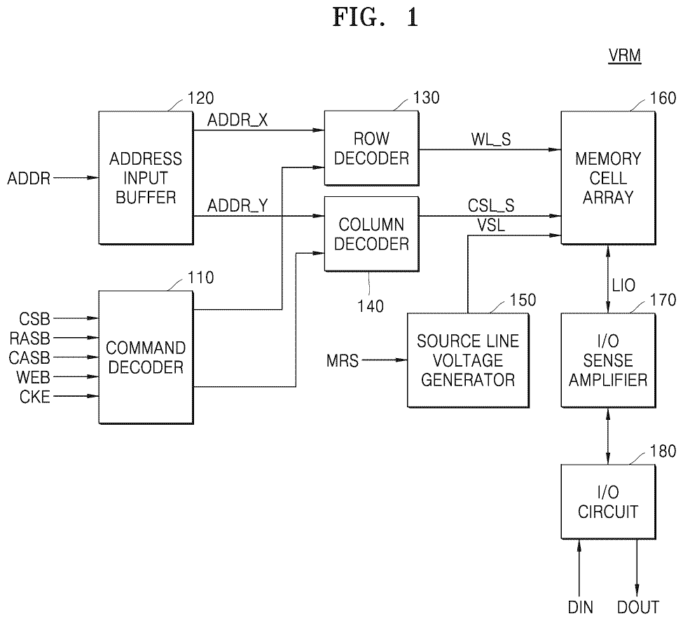

FIG. 1 is a block diagram illustrating a variable resistance memory device VRM according to at least one embodiment.

In detail, an example of the variable resistance memory device VRM may include a magnetic resistance memory device. The magnetic resistance memory device may be a magnetic random access memory (RAM) (MRAM). The variable resistance memory device VRM may include a command decoder 110, an address input buffer 120, a row decoder 130, a column decoder 140, a source line voltage generator 150, a memory cell array 160, an input/output (I/O) sense amplifier 170, and an I/O circuit 180.

The command decoder 110 may be configured to decode a chip selection signal CSB, a row address strobe signal RASB, a column address strobe signal CASB, a write enable signal WEB, and a clock enable signal CKB, to generate a plurality of control signals, and to control circuit blocks of the variable resistance memory device VRM, based on the control signals.

The memory cell array 160 may include a plurality of spin-transfer torque MRAM (STT-MRAM) cells and may be configured to operate in response to a word line driving signal WL_s and a column selection signal CSL_s. The address input buffer 120 may be configured to generate a row address ADDR_X and a column address ADDR_Y, based on an external address ADDR.

The row decoder 130 may be configured to decode the row address ADDR_X to generate a decoded row address and to generate the word line driving signal WL_s, based on the decoded row address. The column decoder 140 may be configured to decode the column address ADDR_Y to generate a decoded column address and to generate the column selection signal CSL_s, based on the decoded column address.

The source line voltage generator 150 may be configured to generate a source line driving voltage VSL, based on an external source voltage, and to supply the source line driving voltage VSL to a source line of the memory cell array 160. The source line voltage generator 150 may be configured to deactivate some or all of circuit blocks configuring the source line voltage generator 150 in a standby mode or a power-down mode. Also, the source line voltage generator 150 may be configured to deactivate some or all of the circuit blocks configuring the source line voltage generator 150, in response to a mode register set signal MRS.

The I/O sense amplifier 170 may be configured to amplify data output through a local I/O line LIO from the memory cell array 160 to output first data and may transfer input data DIN input thereto to the memory cell array 160 through the local I/O line LIO.

The I/O circuit 180 may be configured to determine an output order of the first data, perform parallel-to-serial conversion to generate output data DOUT, and buffer the input data DIN to provide to the I/O sense amplifier 170.

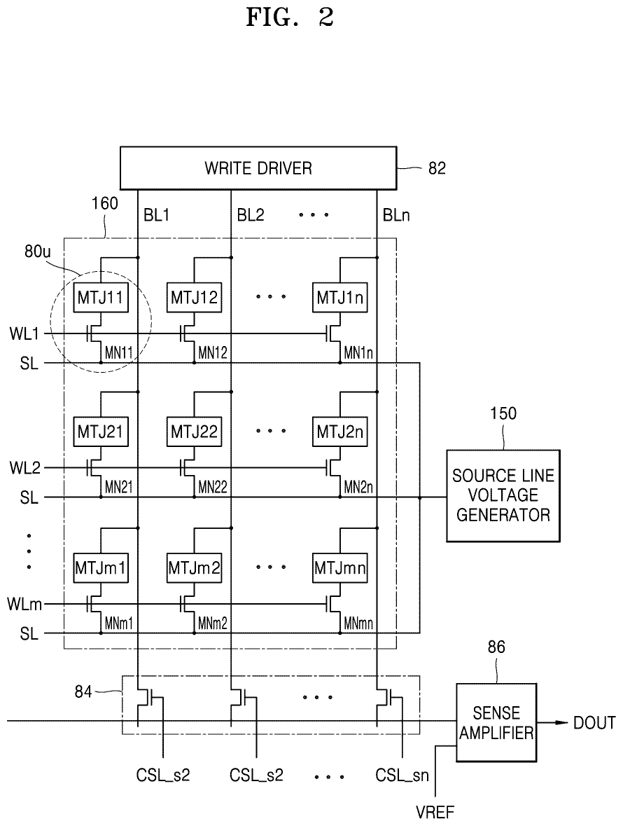

FIG. 2 is a circuit diagram illustrating a memory cell array of the variable resistance memory device VRM of FIG. 1.

In detail, the variable resistance memory device VRM may include a memory cell array 160 as described above. The memory cell array 160 may be referred to as a magneto resistive memory cell array. The memory cell array 160 may be connected to a write driver 82, a selection circuit 84, a source line voltage generator 150, and a sense amplifier 86.

The memory cell array 160 may include a plurality of memory cells 80u. The memory cells 80u may be referred to as magneto resistive memory cells. The memory cell 80u may include a variable resistance layer (e.g., a magnetic tunnel junction (MTJ) layer MTJ11).

The memory cell array 160 may include a plurality of word lines WL1 to WLm and a plurality of bit lines BL1 to BLn. The memory cell array 160 may include the memory cell 80u between each of the word lines WL1 to WLm and each of the bit lines BL1 to BLn.

The memory cell array 160 may include cell transistors MN11 to MNmn each including a gate connected to a corresponding word line of the word lines WL1 to WLm; and MTJ layers MTJ11 to MTJmn which are each connected between a corresponding cell transistor of the cell transistors MN11 to MNmn and a corresponding bit line of the bit lines BL1 to BLn and which include a variable resistance layer.

Sources of the cell transistors MN11 to MN1n may be connected to a source line SL. The selection circuit 84 may connect the bit line BL1 to BLn to the sense amplifier 86 in response to column selection signals CSL_s1 to CSL_sn. The sense amplifier 86 may amplify a difference between an output voltage signal of the selection circuit 84 and a reference voltage VREF to generate output data DOUT.

The write driver 82 may be connected to the bit lines BL1 to BLn and may be configured to generate a program current, based on write data, and to supply the program current to the bit lines BL1 to BLn. To magnetize the MTJ layers MTJ11 to MTJmn of the memory cell array 160, a voltage which is higher than a voltage applied to the bit line BL1 to BLn may be applied to the source line SL. The source line voltage generator 150 may be configured to generate a source line driving voltage VSL to supply the source line driving voltage VSL to source lines SL of the memory cell array 160.

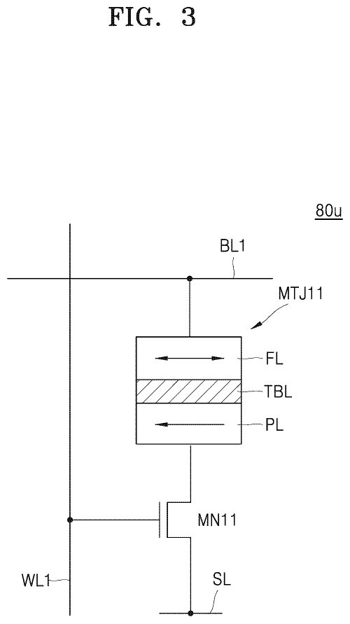

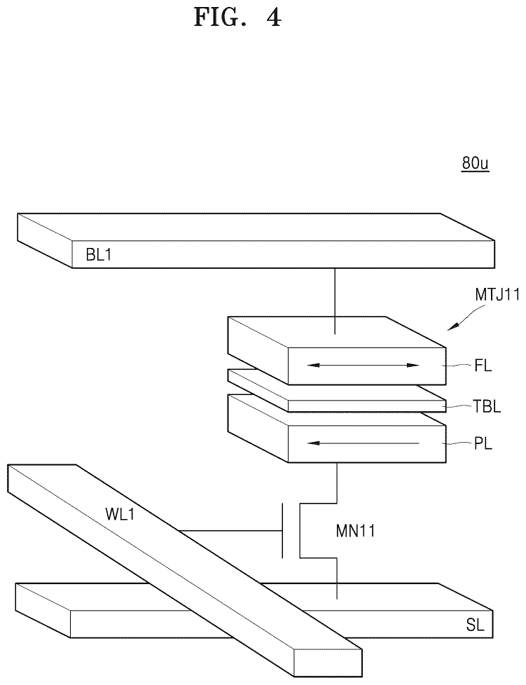

FIG. 3 is a circuit diagram illustrating the memory cell 80u of FIG. 2, and FIG. 4 is a perspective view of the memory cell 80u of FIG. 2.

In detail, the memory cell 80u may include an MTJ layer (e.g., MTJ11) and a cell transistor (e.g., MN11) including an n-channel metal oxide semiconductor (NMOS) transistor. The cell transistor MN11 may include a gate connected to a word line WL1 and a source connected to a source line SL. The MTJ layer MTJ11 may be connected between a drain of the cell transistor MN11 and a bit line BL1.

The MTJ layer MTJ11 may include a pinned layer PL having a fixed constant magnetization direction, a free layer FL which is magnetized in a direction of a magnetic field applied from the outside, and a tunnel barrier layer TBL which is formed of an insulating layer between the pinned layer PL and the free layer FL. The MTJ layer MTJ11 may be included in a cell configuring STT-MRAM.

The free layer FL may include a ferromagnetic material including at least one of cobalt (Co), iron (Fe), and/or nickel (Ni). For example, the free layer FL may include at least one selected from among FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, Y₃FesO₁₂, and/or the like. The free layer FL may be configured to have a changeable magnetization direction during the operation of the memory cell 80u.

The tunnel barrier layer TBL may include a non-magnetic material. For example, the tunnel barrier layer TBL may include at least one selected from among magnesium (Mg), titanium (Ti), aluminum (Al), an oxide of magnesium-zinc (MgZn) and/or magnesium-boron (MgB), nitride of Ti and/or vanadium (V), and/or the like.

The pinned layer PL may include a ferromagnetic material. For example, the pinned layer PL may include at least one selected from among CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, Y₃Fe₅O₁₂ and/or the like. The pinned layer PL may be configured to have a fixed (or pinned) magnetization direction configured to remain fixed during the operation of the memory cell 80u.

To perform a write operation of the STT-MRAM, the cell transistor MN11 may be turned on by applying a logic high voltage to the word line WL1, and a write current may be applied between the bit line BL1 and the source line SL.

To perform a read operation of the STT-MRAM, the cell transistor MN11 may be turned on by applying a logic high voltage to the word line WL1, and by applying a read current toward the source line SL from the bit line BL1, data stored in the memory cell 80u may be determined based on a resistance value of the MTJ layer MTJ11 corresponding to the read current.

The resistance value of the MTJ layer MTJ11 may vary based on a magnetization direction of the free layer FL. For example, the magnetization direction of the free layer FL and a magnetization direction of the pinned layer PL may be arranged in parallel in the MTJ layer MTJ11. In this case, the MTJ layer MTJ11 may have a lower resistance value and may read data ‘0’. Also, the magnetization direction of the free layer FL and the magnetization direction of the pinned layer PL may be arranged in antiparallel in the MTJ layer MTJ11. In this case, the MTJ layer MTJ11 may have a higher resistance value and may read data ‘1’. Additionally, in at least some embodiments, the memory cell 80u may be configured to store data representing a non-binary value (e.g., between 0 and 1).

In FIGS. 2 and 3, a horizontal magnetic device where the magnetization directions of the free layer FL and the pinned layer PL of the MTJ layer MTJ11 are horizontal is illustrated, but in other embodiments, a vertical magnetic device where the magnetization directions of the free layer FL and the pinned layer PL of the MTJ layer MTJ11 are vertical may be used.

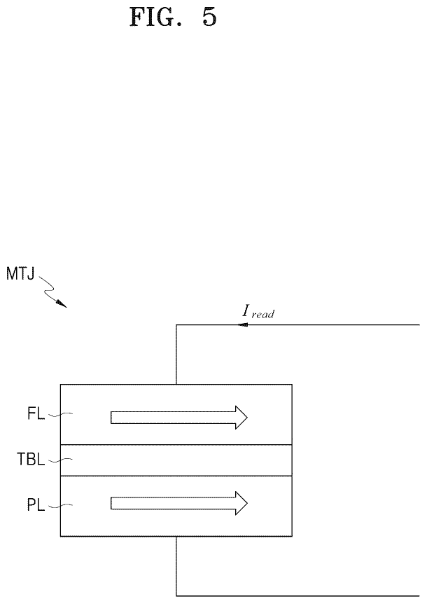

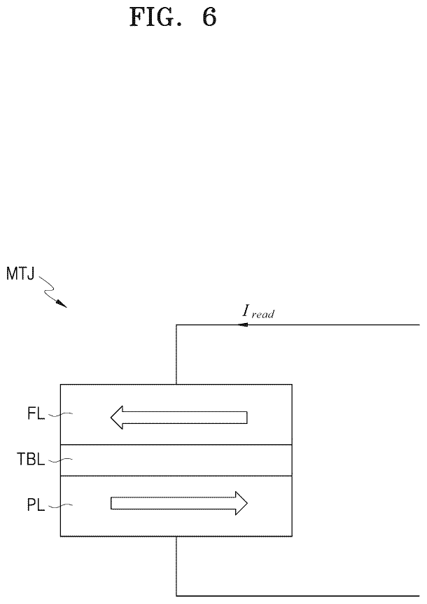

FIGS. 5 and 6 are diagrams to describe a read operation of an MTJ layer of the memory cell 80u of FIG. 2.

In detail, a resistance value of an MTJ layer may vary based on a magnetization directions of a free layer FL. When a read current I_{read} flows in the MTJ layer, a data voltage based on the resistance value of the MTJ layer may be output. Because the intensity of the read current I_{read} is far less than that of a write current, a magnetization direction of the free layer FL may not be changed by the read current I_{read}.

As illustrated in FIG. 5, a magnetization direction of the free layer FL and a magnetization direction of a pinned layer PL may be arranged in parallel in the MTJ layer. Here, the MTJ layer may have a lower resistance value. In this case, data ‘0’ may be read. As illustrated in FIG. 6, a magnetization direction of a free layer FL and a magnetization direction of a pinned layer PL may be arranged in antiparallel in an MTJ layer. Here, the MTJ layer may have a higher resistance value. In this case, data ‘1’ may be read.

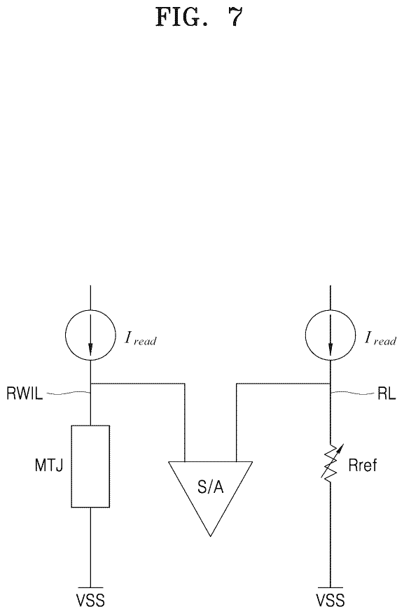

FIG. 7 is a circuit diagram to describe a read operation of an MTJ layer configuring the memory cell 80u of FIG. 2.

In detail, in a read operation of the MTJ layer, a read current I_{read} may be applied to a read wiring line RWIL and a reference wiring line RL of the MTJ layer. The read wiring line RWIL may be a bit line. Therefore, each of an MTJ resistance value of the MTJ layer and a reference resistance value Rref of the reference wiring line RL may be measured. VSS may be a negative terminal.

As described above, when a magnetization direction of a free layer FL and a magnetization direction of a pinned layer PL are arranged in parallel in the MTJ layer, the MTJ layer may have a resistance value which is less than the reference resistance value Rref. Also, when the magnetization direction of the free layer FL and the magnetization direction of the pinned layer PL are arranged in antiparallel in the MTJ layer, the MTJ layer may have a resistance value which is greater than the reference resistance value Rref.

A sense amplifier S/A may amplify a current signal (or a voltage signal), based on a difference between the MTJ resistance value of the MTJ layer and the reference resistance value Rref of the reference wiring line RL, to generate output data DOUT of the MTJ layer. When the MTJ layer has a lower resistance value, data ‘0’ may be output, and when the MTJ layer has a higher resistance value, data ‘1’ may be output. The sense amplifier S/A may be the same as (or substantially similar to) the sense amplifier 86 discussed above.

Except for the MTJ layer, in a memory cell, the reference wiring line RL may be configured to be equal to the read wiring line RWIL. Because the MTJ resistance value of the MTJ layer is compared with the reference resistance value Rref, the MTJ resistance value of the MTJ layer may be arranged in the same direction as the read wiring line RWIL, and thus, a capacitance or a resistance of the reference wiring line RL may be configured to be equal or substantially similar to that of the read wiring line RWIL. Accordingly, a resistance value of the MTJ layer may be more accurately measured in the memory cell.

When a capacitance or a resistance of the reference wiring line RL is equal (or substantially similar) to that of the read wiring line RWIL, a read margin (which is a difference between the reference resistance value Rref and the resistance value of the MTJ layer) may increase. Accordingly, a data value of the MTJ layer may be more accurately measured from the memory cell.

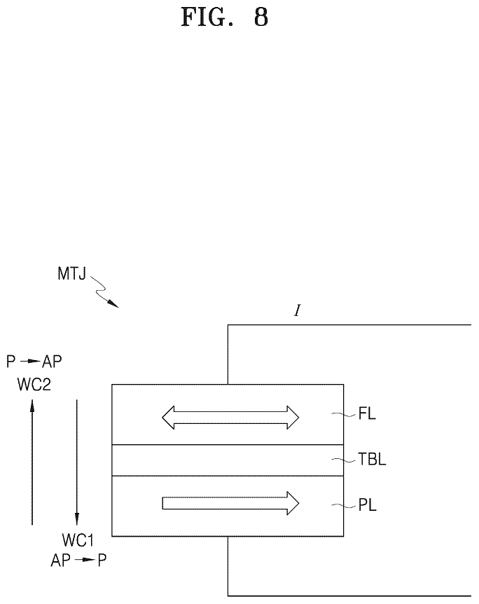

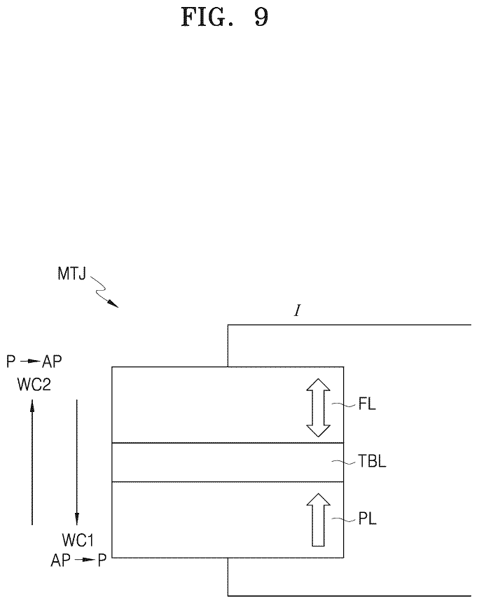

FIGS. 8 and 9 are diagrams to describe a write operation of an MTJ layer of the memory cell of FIG. 2.

In detail, FIG. 8 illustrates a horizontal magnetic device where a magnetization direction of each of a free layer FL and a pinned layer PL of an MTJ layer is horizontal. The MTJ layer where the magnetization direction is horizontal may correspond to a case where a magnetization easy axis and a movement direction of a current are substantially perpendicular to each other. FIG. 9 illustrates a vertical magnetic device where a magnetization direction of each of a free layer FL and a pinned layer PL is vertical. An MTJ layer where the magnetization direction is vertical may correspond to a case where a magnetization easy axis and a movement direction of a current are substantially parallel to each other.

The magnetization direction of the free layer FL may be determined based on directions of write currents (for example, first and second write currents) WC1 and WC2 flowing in the MTJ layer. For example, when the first write current WC1 is applied, free electrons having the same spin direction as the pinned layer PL may apply torque to the free layer FL. Based thereon, the free layer FL may be magnetized in parallel (P) with the pinned layer PL.

When the second write current WC2 is applied, free electrons having spin opposite to the pinned layer PL may return to the free layer FL and may apply torque to the free layer FL. Based thereon, the free layer FL may be magnetized in antiparallel (AP) with the pinned layer PL. That is, the magnetization direction of the free layer FL in the MTJ layer may be changed by spin-transfer torque (STT).

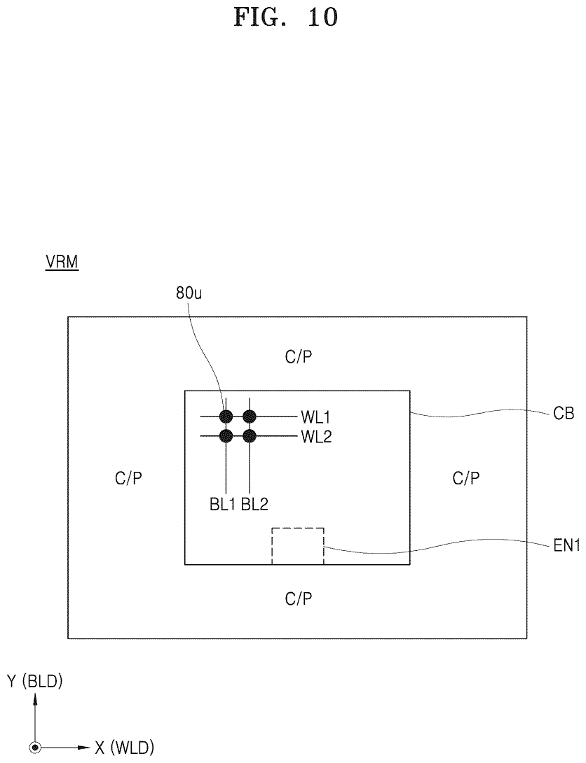

FIG. 10 is an enlarged plan view to describe a variable resistance memory device VRM according to at least one embodiment.

In detail, the variable resistance memory device VRM may include a memory cell region CB configuring a memory cell array (160 of FIG. 1) and a core/peripheral circuit region C/P disposed at a perimeter of the memory cell region CB. The memory cell region CB may be referred to as a memory cell block.

The memory cell region CB may include a plurality of word lines WL1 and WL2 disposed on a substrate and a plurality of bit lines BL1 and BL2. In FIG. 10, for convenience, only two word lines WL1 and WL2 and two bit lines BL1 and BL2 are illustrated. The word lines WL1 and WL2 may be disposed to extend in an X direction (e.g., a word line direction WLD or a first direction) on the substrate.

The bit lines BL1 and BL2 may be disposed to extend in a Y direction (e.g., a bit line direction BLD or a second direction) perpendicular to the X direction (the word line direction). A memory cell 80u may be disposed in an intersection region between the word lines WL1 and WL2 and the bit lines BL1 and BL2. The memory cell 80u may be an STT-MRAM cell. In FIG. 10, a reference numeral EN1 may refer to an edge portion of the memory cell region CB.

The core/peripheral circuit region C/P may be a region for driving the memory cell region CB configuring the memory cell array (160 of FIG. 1). For example, a row decoder (130 of FIG. 1), a column decoder (140 of FIG. 1), and a source line voltage generator (150 of FIG. 1) may be disposed in the core/peripheral circuit region C/P. Also, a sense amplifier region and a sub word line driver region may be disposed in the core/peripheral circuit region C/P.

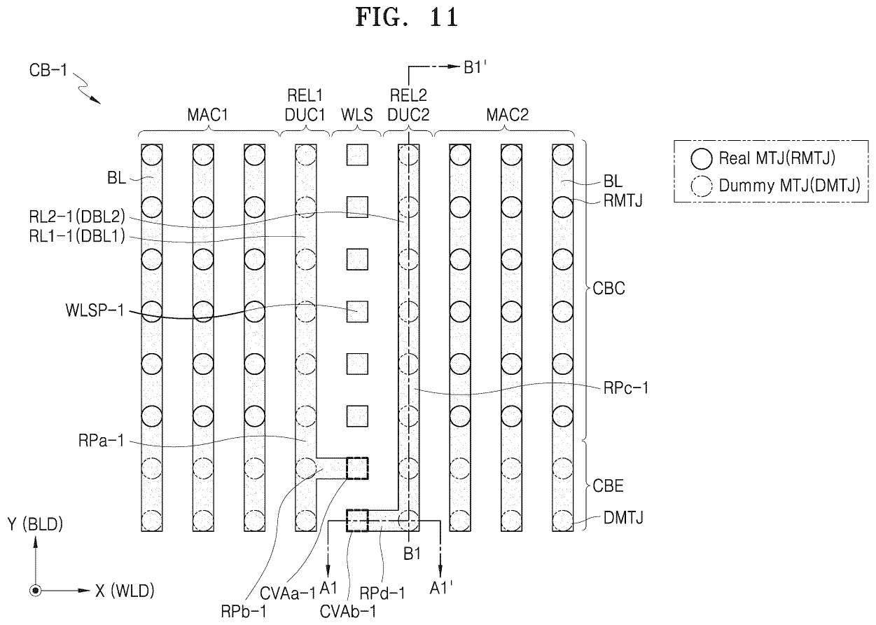

FIG. 11 is an enlarged plan view to describe a memory cell region of a variable resistance memory device according to at least one embodiment.

In detail, a memory cell region CB-1 may be an enlarged view of an edge portion EN1 of the memory cell region CB of FIG. 10. The memory cell region CB-1 may include a first main cell region MAC1, a first dummy cell region DUC1, a word line strap region WLS, a second dummy cell region DUC2, and a second main cell region MAC2 in a word line direction WLD (e.g., a first direction or an X direction).

The first dummy cell region DUC1 may be a first reference wiring region REL1. The second dummy cell region DUC2 may be a second reference wiring region REL2. The memory cell region CB-1 may include a cell edge region CBE and a cell center region CBC in a bit line direction BLD (e.g., a second direction or a Y direction).

A plurality of real MTJ layers RMTJ may be disposed in the bit line direction BLD in the first main cell region MAC1. The real MTJ layers RMTJ may be included in memory cells. In the following description, the real MTJ layers RMTJ may be referred to as RMTJ layers.

A plurality of dummy MTJ layers DMTJ may be disposed in a cell edge region CBE of the first main cell region MAC1. The dummy MTJ layers DMTJ may be included in dummy memory cells. In the following description, the dummy MTJ layers DMTJ may be referred to as DMTJ layers. A bit line BL may be disposed in the bit line direction BLD on the RMTJ layers and the DMTJ layers of the first memory cell region MAC1.

The first dummy cell region DUC1 and the first reference wiring region REL1 may be disposed apart from and adjacent to the first main cell region MAC1 in the word line direction WLD. DMTJ layers may be disposed in the cell edge region CBE and the cell center region CBC, in the first dummy cell region DUC1 and the first reference wiring region REL1.

A first reference wiring line RL1-1 may be disposed in the bit line direction BLD on the DMTJ layers of the first dummy cell region DUC1 and the first reference wiring region REL1. The first reference wiring line RL1-1 may be a first dummy bit line DBL1. The first reference wiring line RL1-1, like the bit line BL, may be disposed in the bit line direction BLD.

The first reference wiring line RL1-1 may have a resistance and/or a capacitance which is equal or substantially similar to that of the bit line BL, in a read operation of the RMTJ layers. The first reference wiring line RL1-1 may include a first reference wiring pattern RPa-1 disposed on and under the DMTJ layers and a first reference extension wiring pattern RPb-1 extending in the word line direction WLD from the first reference wiring pattern RPa-1. The first reference extension wiring pattern RPb-1 may be disposed in the cell edge region CBE.

The word line strap region WLS may be disposed apart from and adjacent to the first dummy cell region DUC1 and the first reference wiring region REL1 in the word line direction WLD. The word line strap region WLS may be disposed apart from and adjacent to the first dummy cell region DUC1 and the second dummy cell region DUC2 in the word line direction WLD.

The word line strap region WLS may include a plurality of word line strap patterns WLSP-1. The word line strap patterns WLSP-1 may be disposed apart from one another in the bit line direction BLD.

The word line strap patterns WLSP-1 may be contact patterns. The word line strap patterns WLSP-1 may be contact patterns connected to lower metal patterns which strap adjacent word lines, in an inactive region.

The word line strap patterns WLSP-1 may decrease a resistance of a word line in an operation of a memory cell. The word line strap patterns WLSP-1 may include a first cell via pattern CVAa-1 connected to the first reference extension wiring pattern RPb-1.

The second dummy cell region DUC2 and the second reference wiring region REL2 may be disposed apart from and adjacent to the word line strap region WLS in the word line direction WLD. DMTJ layers may be disposed in the cell edge region CBE and the cell center region CBC, in the second dummy cell region DUC2 and the second reference wiring region REL2.

A second reference wiring line RL2-1 may be disposed in the bit line direction BLD on the DMTJ layers of the second dummy cell region DUC2 and the second reference wiring region REL2. The second reference wiring line RL2-1 may be a second dummy bit line DBL2.

The second reference wiring line RL2-1, like the bit line BL, may be disposed in the bit line direction BLD. The second reference wiring line RL2-1 may have a resistance and/or a capacitance which is equal or substantially similar to that of the bit line BL, in a read operation of the RMTJ layers. The second reference wiring line RL2-1 may include a second reference wiring pattern RPc-1 disposed on and under the DMTJ layers and a second reference extension wiring pattern RPd-1 extending in the word line direction WLD from the second reference wiring pattern RPc-1. The second reference extension wiring pattern RPd-1 may be disposed in the cell edge region CBE.

The second reference extension wiring pattern RPd-1 may be connected to a second cell via pattern CVAb-1 configuring the word line strap patterns WLSP-1. Therefore, the word line strap patterns WLSP-1 may include the second cell via pattern CVAb-1 connected to the second reference extension wiring pattern RPd-1.

The first cell via pattern CVAa-1 and the second cell via pattern CVAb-1 may be disposed in the cell edge region CBE. The first cell via pattern CVAa-1 and the second cell via pattern CVAb-1 may be disposed adjacent to each other in the bit line direction BLD.

The second main cell region MAC2 may be disposed apart from and adjacent to the second dummy cell region DUC2 and the second reference wiring region REL2 in the word line direction WLD. RMTJ layers may be disposed in the bit line direction BLD in the second main cell region MAC2.

DMTJ layers may be disposed in the cell edge region CBE of the second main cell region MAC2. A bit line BL may be disposed in the bit line direction BLD on the RMTJ layers and the DMTJ layers of the second memory cell region MAC2.

In FIG. 11, DMTJ layers of two rows may be disposed in the bit line direction BLD in the cell edge region CBE of the memory cell region CB-1, but in some embodiments, DMTJ layers of a (e.g., one) row may be disposed.

The memory cell region CB-1 may have a symmetric structure in the word line direction WLD with respect to the word line strap region WLS. Therefore, the second reference wiring region REL2 may correspond to the first reference wiring region REL1. The second reference wiring line RL2-1 may correspond to the first reference wiring line RL1-1. The second reference wiring pattern RPc-1 and the second reference extension wiring pattern RPd-1 may respectively correspond to the first reference wiring pattern RPa-1 and the second reference extension wiring pattern RPb-1.

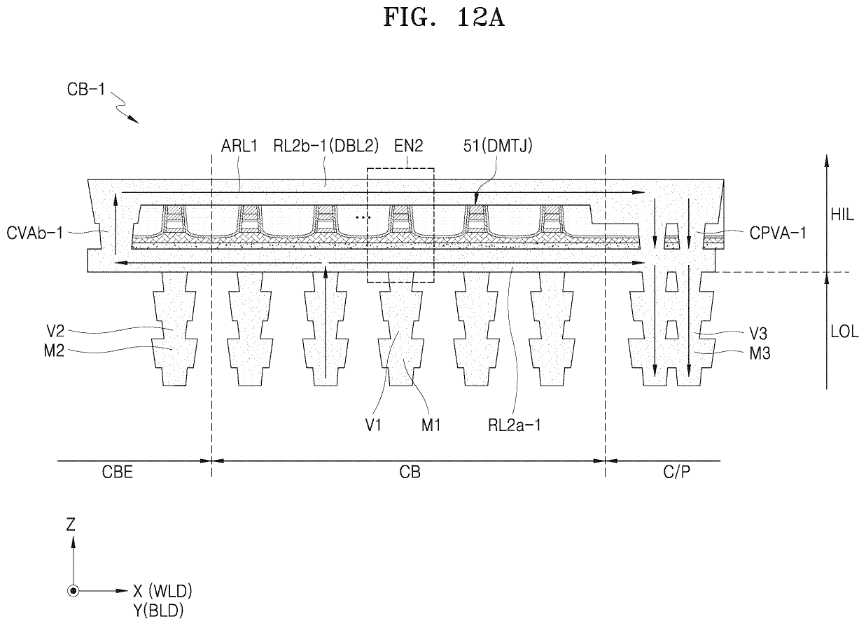

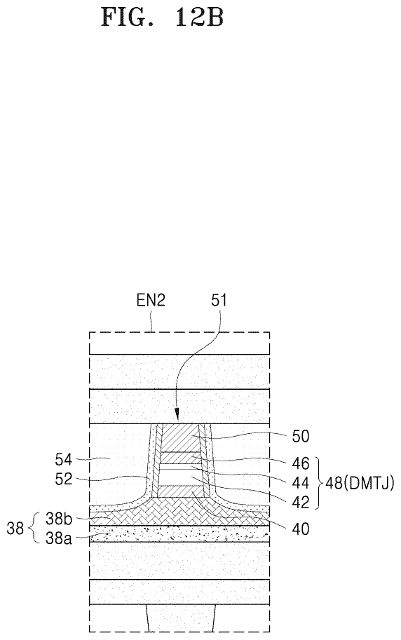

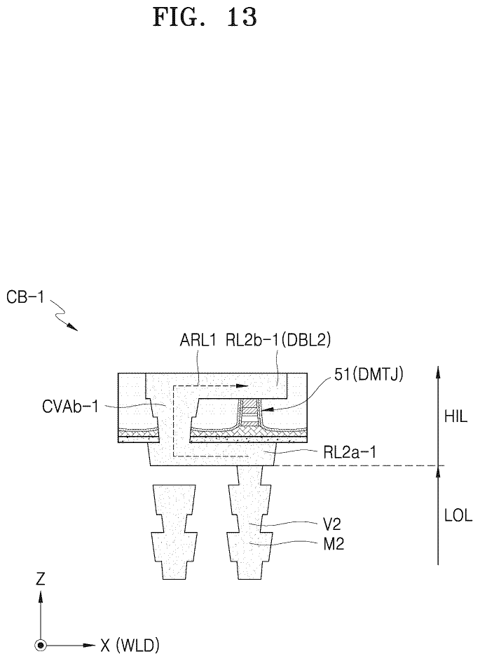

FIG. 12A is a main cross-sectional view in a word line direction and a bit line direction of FIG. 11, FIG. 12B is a partial enlarged view of FIG. 12A, and FIG. 13 is a main cross-sectional view in the word line direction of FIG. 11.

In detail, FIG. 12A is a main cross-sectional view taken along line A1-B1-B1′ of FIG. 11. FIG. 12B is a partial enlarged view of a region EN2 of FIG. 12A. FIG. 13 is a main cross-sectional view taken along line A1-A1′ of FIG. 11.

As illustrated in FIG. 12A, a memory cell region CB-1 may include a cell edge region CBE and a cell center region CBC. In FIG. 12A, a core/peripheral circuit region C/P disposed at one side of the memory cell region CB-1 is further illustrated. FIG. 12 illustrates only the cell edge region CBE. The memory cell region CB-1 and the core/peripheral circuit region C/P may configure the variable resistance memory device VRM of FIG. 10.

A plurality of first wiring layers M1 disposed on a substrate and a plurality of first via layers V1 connecting the first wiring layers M1 with each other may be provided in the cell center region CBC. A plurality of second wiring layers M2 disposed on the substrate and a plurality of second via layers V2 connecting the second wiring layers M2 with each other may be provided in the cell edge region CBE.

A plurality of third wiring layers M3 disposed on the substrate and a plurality of third via layers V3 connecting the third wiring layers M3 with each other may be provided in the core/peripheral circuit region C/P. The first wiring layers M1, the first via layers V1, the second wiring layers M2, the second via layers V2, the third wiring layers M3, and the third via layers V3 may configure a lower wiring level layer LOL. The lower wiring level layer LOL may be insulated by a lower interlayer insulation layer. In FIGS. 12A and 13, a source line, a cell transistor, and a word line are not illustrated for clarity and convenience.

A second lower reference wiring line RL2a-1 may be disposed on the lower wiring level layer LOL. The second lower reference wiring line RL2a-1 may be disposed in the same shape as the second reference wiring line RL2-1 of FIG. 10. The second lower reference wiring line RL2a-1 may be connected to the first via layers V1, the second via layers V2, and the third via layers V3.

A pad isolation insulation layer 38 and a plurality of dummy variable resistance pattern structures 51 may be disposed on the second lower reference wiring line RL2a-1 of the cell center region CBC and the cell edge region CBE. The dummy variable resistance pattern structures 51 may include DMTJ layers. In FIG. 12A, for convenience, only one dummy variable resistance pattern structure 51 is illustrated in the cell edge region CBE; however this is only an example and the cell edge region CBE may include one or more dummy variable resistance pattern structures 51. Each of the dummy variable resistance pattern structures 51 may include a lower electrode 40, a DMTJ layer, and an upper electrode 50.

A capping layer pattern 52 may be formed on a surface of the pad isolation insulation layer 38 to cover a sidewall of each of the dummy variable resistance pattern structures 51. A buried insulation layer pattern 54 filled between the dummy variable resistance pattern structures 51 may be formed on the capping layer pattern 52 and the pad isolation insulation layer 38.

A second cell via pattern CVAb-1 may be formed on the second lower reference wiring line RL2a-1 of the cell edge region CBE. The second cell via pattern CVAb-1 may be formed on a second lower reference wiring line RL2a-1 of one end of the cell edge region CBE which does not overlap the dummy variable resistance pattern structures 51. A first core/peripheral via pattern CPVA-1 may be formed on a second lower reference wiring line RL2a-1 of the core/peripheral circuit region C/P.

A second upper reference wiring line RL2b-1 may be disposed on the dummy variable resistance pattern structures 51 and the buried insulation layer pattern 54. The second upper reference wiring line RL2b-1 may be disposed in the same shape as the second reference wiring line RL2-1 of FIG. 10. The second lower reference wiring line RL2a-1 and the second upper reference wiring line RL2b-1 may correspond to the second reference wiring line RL2-1 of FIG. 10.

The second lower reference wiring line RL2a-1, the second cell via pattern CVAb-1, the first core/peripheral via pattern CPVA-1, and the second upper reference wiring line RL2b-1 may configure an upper wiring level layer HIL. The upper wiring level layer HIL may be insulated by the buried insulation layer pattern 54.

The second upper reference wiring line RL2b-1 may be connected to one end portion of the second lower reference wiring line RL2a-1 through the second cell via pattern CVAb-1, in the cell edge region CBE. The second upper reference wiring line RL2b-1 may be connected to the one end portion of the second lower reference wiring line RL2a-1 through the first core/peripheral via pattern CPVA-1, in the core/peripheral circuit region C/P.

In the memory cell region CB-1 illustrated in FIGS. 11, 12A, 12B, and 13, as illustrated in FIGS. 12A and 13, a metal path ARL1 which does not pass through DMTJ layers may be formed in a read operation of the RMTJ layers disposed in the cell center region CBC. The metal path ARL1 may be a path which passes through the second lower reference wiring line RL2a-1, the second cell via pattern CVAb-1, and the second upper reference wiring line RL2b-1.

In FIG. 12A, the metal path ARL1 may be a path which passes through the first wiring layers M1, the first via layers V1, the second lower reference wiring line RL2a-1, the second cell via pattern CVAb-1, the second upper reference wiring line RL2b-1, the first core/peripheral via pattern CPVA-1, the third wiring layers M3, and the third via layers V3. The metal path ARL1 may also be referred to as a signal path or an electrical path.

The memory cell region CB-1 may include a second reference wiring line RL2-1 (e.g., the second upper reference wiring line RL2b-1) disposed in the same direction as the bit line BL by using the second cell via pattern CVAb-1 in a read operation of the RMTJ layers disposed in the cell center region CBC.

Therefore, a resistance and/or a capacitance of the second reference wiring line RL2-1 may be configured to be equal or substantially similar to the bit line BL (or a read wiring line). Accordingly, a read margin which is a difference between resistance values of the MTJ layers and a resistance value of the second reference wiring line RL2-1 in the memory cell region CB-1 may increase.

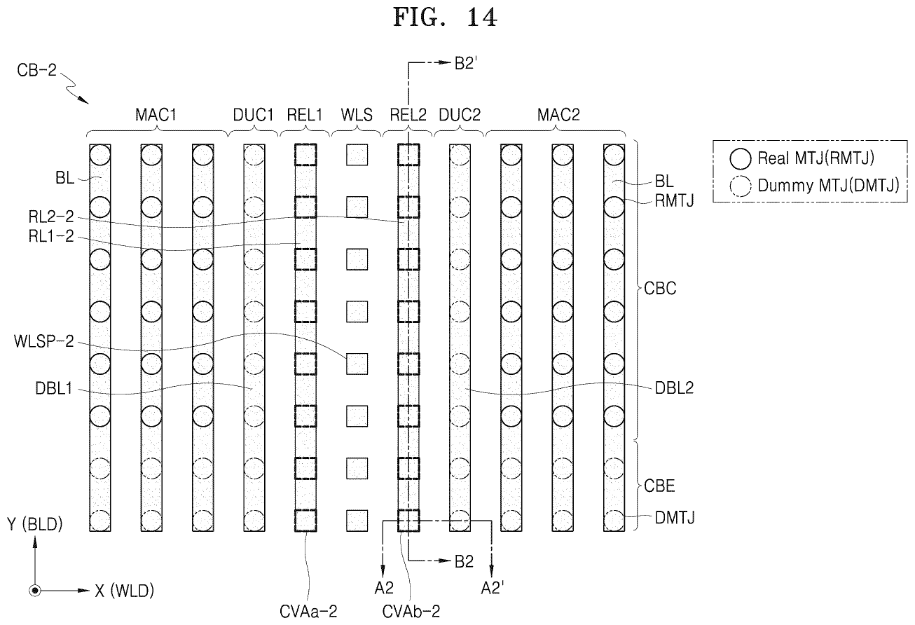

FIG. 14 is an enlarged plan view to describe a memory cell region of a variable resistance memory device according to at least one embodiment.

In detail, a memory cell region CB-2 may be an enlarged view of the edge portion EN1 of the memory cell region CB of FIG. 10. Except for the arrangement of a first dummy cell region DUC1, a first reference wiring region REL1, a word line strap region WLS, a second reference wiring region REL2, and a second dummy cell region DUC2 differs from FIG. 11, the memory cell region CB-2 may be the same as FIG. 11. In FIG. 14, the same reference numerals as FIG. 11 refer to like elements. In FIG. 14, description which is the same as or substantially similar to the description of FIG. 11 may be briefly given or omitted.

The memory cell region CB-2 may include a first main cell region MAC1, a first dummy cell region DUC1, a first reference wiring region REL1, a word line strap region WLS, a second reference wiring region REL2, a second dummy cell region DUC2, and a second main cell region MAC2 in a word line direction WLD. The memory cell region CB-2 may include a cell edge region CBE and a cell center region CBC in a bit line direction BLD.

RMTJ layers and DMTJ layers may be disposed in the bit line direction BLD in the first main cell region MAC1. A bit line BL may be disposed in the bit line direction BLD on the RMTJ layers and the DMTJ layers of the first memory cell region MAC1.

The first dummy cell region DUC1 may be disposed adjacent to the first main cell region MAC1 in the word line direction WLD. DMTJ layers may be disposed in a cell edge region CBE and a cell center region CBC of the first dummy cell region DUC1. A first dummy bit line DBL1 may be disposed in the bit line direction BLD on the DMTJ layers of the first dummy cell region DUC1.

The first reference wiring region REL1 may be disposed adjacent to the first dummy cell region DUC1 in the word line direction WLD. A first reference wiring line RL1-2 may be disposed in the bit line direction BLD in the first reference wiring region REL1.

The first reference wiring line RL1-2, like the bit line BL, may be disposed in the bit line direction BLD. The first reference wiring line RL1-1 may have a resistance and/or a capacitance which is equal or substantially similar to that of the bit line BL, in a read operation of the RMTJ layers.

The first reference wiring region REL1 may include a first cell via pattern CVAa-2 disposed under the first reference wiring line RL1-2. The first cell via pattern CVAa-2, as described below, may be connected to first wiring layers M1, first via layers V1, second wiring layers M2, and second via layers V2 of the cell edge region CBE and the cell center region CBC.

The word line strap region WLS may be disposed adjacent to the first reference wiring region REL1 in the word line direction WLD. The word line strap region WLS may include a plurality of word line strap patterns WLSP-2. The word line strap patterns WLSP-2 may be disposed apart from one another in the bit line direction BLD.

The second reference wiring region REL2 may be disposed adjacent to the word line strap region WLS in the word line direction WLD. A second reference wiring line RL2-2 may be disposed in the bit line direction BLD in the second reference wiring region REL2.

The second reference wiring line RL2-2, like the bit line BL, may be disposed in the bit line direction BLD. The second reference wiring line RL2-2 may have a resistance and/or a capacitance which is equal or substantially similar to that of the bit line BL, in a read operation of the RMTJ layers.

The second reference wiring region REL2 may include a second cell via pattern CVAb-2 disposed under the second reference wiring line RL2-2. The second cell via pattern CVAb-2, as described below, may be connected to first wiring layers M1, first via layers V1, second wiring layers M2, and second via layers V2 of the cell edge region CBE and the cell center region CBC.

The second dummy cell region DUC2 may be disposed adjacent to the second reference wiring region REL2 in the word line direction WLD. DMTJ layers may be disposed in a cell edge region CBE and a cell center region CBC of the second dummy cell region DUC2. A second dummy bit line DBL2 may be disposed in the bit line direction BLD on the DMTJ layers of the second dummy cell region DUC2.

The second main cell region MAC2 may be disposed adjacent to the second dummy cell region DUC2 in the word line direction WLD. RMTJ layers may be disposed in the bit line direction BLD in the second main cell region MAC2. DMTJ layers may be disposed in the cell edge region CBE of the second main cell region MAC2. A bit line BL may be disposed in the bit line direction BLD on the RMTJ layers and the DMTJ layers of the second memory cell region MAC2.

The memory cell region CB-2 may have a symmetric structure in the word line direction WLD with respect to the word line strap region WLS. Therefore, the second reference wiring region REL2 may correspond to the first reference wiring region REL1. The second reference wiring line RL2-2 may correspond to the first reference wiring line RL1-2.

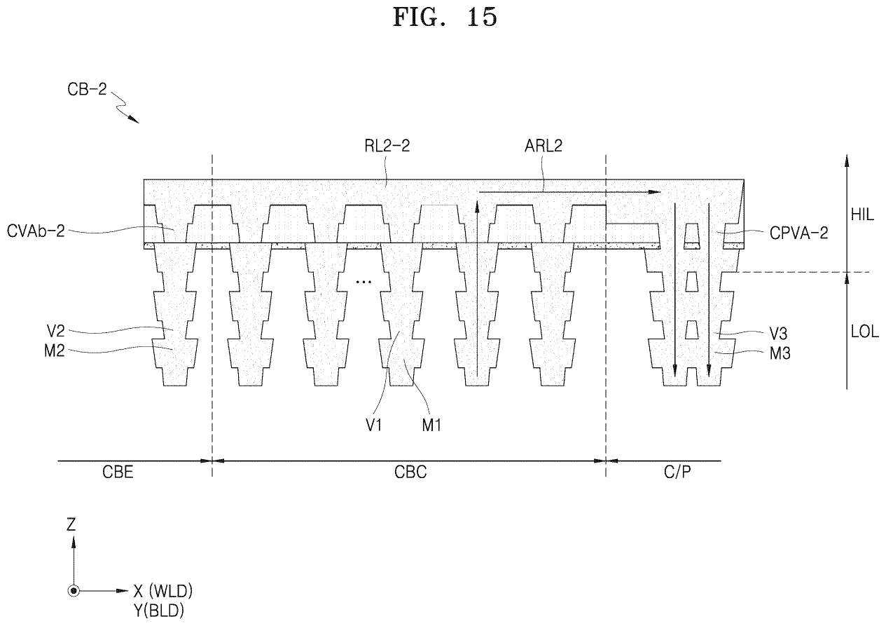

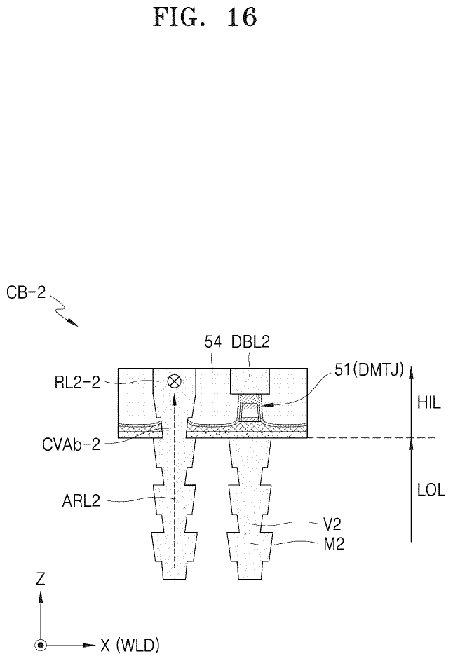

FIG. 15 is a main cross-sectional view in a bit line direction of FIG. 14, and FIG. 16 is a main cross-sectional view in a word line direction of FIG. 14.

In detail, FIG. 15 is a main cross-sectional view taken along line B2-B2′ of FIG. 14. FIG. 16 is a main cross-sectional view taken along line A2-A2′ of FIG. 14. In FIGS. 15 and 16, the same reference numerals as FIGS. 12A, 12B, and 13 refer to like elements. In FIGS. 15 and 16, descriptions which are the same as or substantially similar to the descriptions of FIGS. 12A, 12B, and 13 may be briefly given or omitted.

As illustrated in FIG. 15, a memory cell region CB-2 may include a cell edge region CBE and a cell center region CBC. In FIG. 15, a core/peripheral circuit region C/P disposed at one side of the memory cell region CB-2 is further illustrated. FIG. 16 illustrates only the cell edge region CBE. The memory cell region CB-2 and the core/peripheral circuit region C/P may configure the variable resistance memory device VRM of FIG. 10.

The cell center region CBC may include a plurality of first wiring layers M1 and a plurality of first via layers V1. The cell edge region CBE may include a plurality of second wiring layers M2 and a plurality of second via layers V2. The core/peripheral circuit region C/P may include a plurality of third wiring layers M3 and a plurality of third via layers V3.

The first wiring layers M1, the first via layers V1, the second wiring layers M2, the second via layers V2, the third wiring layers M3, and the third via layers V3 may configure a lower wiring level layer LOL. The lower wiring level layer LOL may be insulated by a lower interlayer insulation layer.

A second cell via pattern CVAb-2 may be disposed on the lower wiring level layer LOL. The second cell via pattern CVAb-2 may be formed on the first wiring layers M1 of the cell center region CBC and the second wiring layers M2 of the cell edge region CBE. The second cell via pattern CVAb-2 may not overlap DMTJ layers. A first core/peripheral via pattern CPVA-2 may be formed on the third wiring layers M3 of the core/peripheral circuit region C/P. The second cell via pattern CVAb-2 and the first core/peripheral via pattern CPVA-2 may be insulated by a buried insulation layer pattern 54.

A second reference wiring line RL2-2 may be disposed on the second cell via pattern CVAb-2 and the first core/peripheral via pattern CPVA-2. The second reference wiring line RL2-2 may configure an upper wiring level layer HIL. The upper wiring level layer HIL may be insulated by the buried insulation layer pattern 54.

The second reference wiring line RL2-2 may be connected to the first wiring layers M1 and the second wiring layers M2 through the second cell via pattern CVAb-2, in the cell edge region CBE and the cell center region CBC. The second reference wiring line RL2-2 may be connected to the third wiring layers M3 through the first core/peripheral via pattern CPVA-2, in the core/peripheral circuit region C/P.

As illustrated in FIG. 16, a dummy variable resistance pattern structure 51 may be disposed in the cell edge region CBE. The dummy variable resistance pattern structure 51 may include DMTJ layers. A second dummy bit line DBL2 may be disposed on the dummy variable resistance pattern structure 51.

In the memory cell region CB-2, as illustrated in FIGS. 15 and 16, a metal path ARL2 which does not pass through the DMTJ layers may be formed in a read operation of RMTJ layers disposed in the cell center region CBC. The metal path ARL2 may be a path which passes through the first wiring layers M1, the second cell via pattern CVAb-2, and the second reference wiring line RL2-2.

In FIG. 15, the metal path ARL2 may be a path which passes through the first wiring layers M1, the second cell via pattern CVAb-2, the second reference wiring line RL2-2, the first core/peripheral via pattern CPVA-1, and the third wiring layers M3.

The memory cell region CB-2 may include the second reference wiring line RL2-2 disposed in the same direction as the bit line BL by using the second cell via pattern CVAb-2 in a read operation of the RMTJ layers disposed in the cell center region CBC.

Therefore, a resistance and/or a capacitance of the second reference wiring line RL2-1 may be configured to be equal or substantially similar to the bit line BL (or a read wiring line). Accordingly, a read margin which is a difference between resistance values of the MTJ layers and a resistance value of the second reference wiring line RL2-2 in the memory cell region CB-2 may increase.

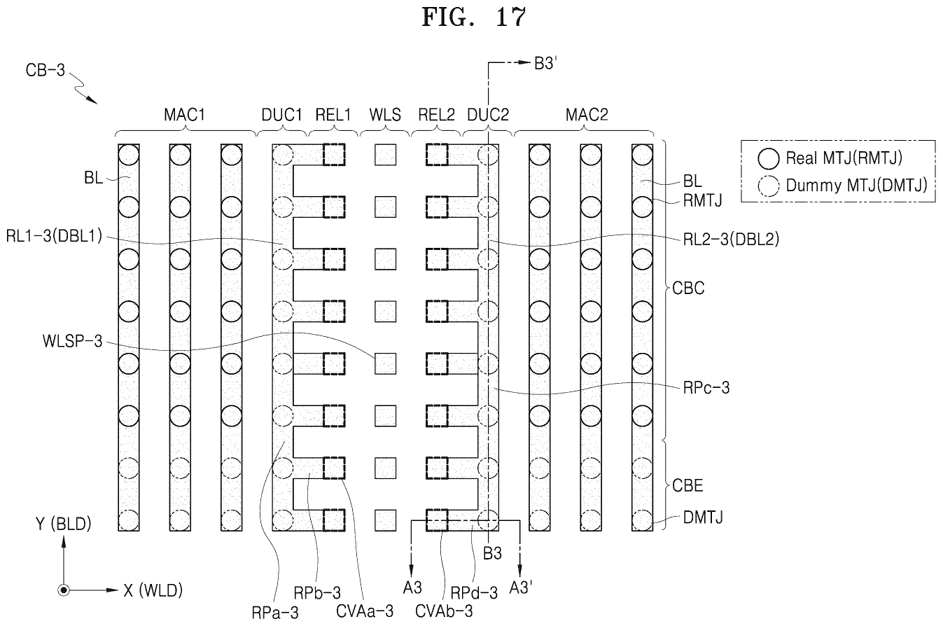

FIG. 17 is an enlarged plan view to describe a memory cell region of a variable resistance memory device according to at least one embodiment.

In detail, a memory cell region CB-3 may be an enlarged view of the edge portion EN1 of the memory cell region CB of FIG. 10. Except for the arrangement of a first dummy cell region DUC1, a first reference wiring region REL1, a word line strap region WLS, a second reference wiring region REL2, and a second dummy cell region DUC2 which differs from FIG. 11, the memory cell region CB-3 may be the same as FIG. 11. In FIG. 17, the same reference numerals as FIG. 11 refer to like elements. In FIG. 17, description which is the same as or substantially similar to the description of FIG. 11 may be briefly given or omitted.

The memory cell region CB-3 may include a first main cell region MAC1, a first dummy cell region DUC1, a word line strap region WLS, a second dummy cell region DUC2, and a second main cell region MAC2 in a word line direction WLD. The first dummy cell region DUC1 may be a first reference wiring region REL1. The second dummy cell region DUC2 may be a second reference wiring region REL2. The memory cell region CB-3 may include a cell edge region CBE and a cell center region CBC in a bit line direction BLD.

RMTJ layers and DMTJ layers may be disposed in the bit line direction BLD in the first main cell region MAC1. A bit line BL may be disposed in the bit line direction BLD on the RMTJ layers and the DMTJ layers of the first memory cell region MAC1.

The first dummy cell region DUC1 and the first reference wiring region REL1 may be disposed adjacent to the first main cell region MAC1 in the word line direction WLD. DMTJ layers may be disposed in the cell edge region CBE and the cell center region CBC, in the first dummy cell region DUC1 and the first reference wiring region REL1.

A first reference wiring line RL1-3 may be disposed in the bit line direction BLD on the DMTJ layers of the first dummy cell region DUC1 and the first reference wiring region REL1. The first reference wiring line RL1-3 may be a first dummy bit line DBL1. The first reference wiring line RL1-3, like the bit line BL, may be disposed in the bit line direction BLD.

The first reference wiring line RL1-3 may have a resistance and/or a capacitance which is equal or substantially similar to that of the bit line BL, in a read operation of the RMTJ layers. The first reference wiring line RL1-3 may include a first reference wiring pattern RPa-3 disposed on and under the DMTJ layers and a first reference extension wiring pattern RPb-3 extending in the word line direction WLD from the first reference wiring pattern RPa-3.

The first reference extension wiring pattern RPb-3 may be disposed in the cell edge region CBE and the cell center region CBC. The first reference extension wiring pattern RPb-3 may be disposed on and under DMTJ layers disposed in the cell edge region CBE and the cell center region CBC.

The first reference wiring region REL1 may include a first cell via pattern CVAa-3 connected to the first reference wiring line RL1-3, namely, the first reference extension wiring pattern RPb-3. The first cell via pattern CVAa-3, as described below, may be connected to first wiring layers M1, first via layers V1, second wiring layers M2, and second via layers V2 of the cell edge region CBE and the cell center region CBC.

The word line strap region WLS may be disposed adjacent to the first reference wiring region REL1 in the word line direction WLD. The word line strap region WLS may include a plurality of word line strap patterns WLSP-3. The word line strap patterns WLSP-3 may be disposed apart from one another in the bit line direction BLD.

The second dummy cell region DUC2 and the second reference wiring region REL2 may be disposed adjacent to the word line strap region WLS in the word line direction WLD. DMTJ layers may be disposed in the cell edge region CBE and the cell center region CBC, in the second dummy cell region DUC2 and the second reference wiring region REL2.

A second reference wiring line RL2-3 may be disposed in the bit line direction BLD on the DMTJ layers of the second dummy cell region DUC2 and the second reference wiring region REL2. The second reference wiring line RL2-3 may be a second dummy bit line DBL2.

The second reference wiring line RL2-3, like the bit line BL, may be disposed in the bit line direction BLD. The second reference wiring line RL2-3 may have a resistance and/or a capacitance which is equal or substantially similar to that of the bit line BL, in a read operation of the RMTJ layers. The second reference wiring line RL2-3 may include a second reference wiring pattern RPc-3 disposed on and under the DMTJ layers and a second reference extension wiring pattern RPd-3 extending in the word line direction WLD from the second reference wiring pattern RPc-3.

The second reference extension wiring pattern RPd-3 may be disposed in the cell edge region CBE and the cell center region CBC. The second reference extension wiring pattern RPd-3 may be disposed on and under DMTJ layers disposed in the cell edge region CBE and the cell center region CBC.

The second reference wiring region REL2 may include a second cell via pattern CVAb-3 connected to the second reference wiring line RL2-3, namely, the second reference extension wiring pattern RPd-3. The second cell via pattern CVAb-3, as described below, may be connected to first wiring layers M1, first via layers V1, second wiring layers M2, and second via layers V2 of the cell edge region CBE and the cell center region CBC.

The first cell via pattern CVAa-3 and the second cell via pattern CVAb-3 may be disposed in the cell center region CBC and the cell edge region CBE. The first cell via pattern CVAa-3 and the second cell via pattern CVAb-3 may be disposed adjacent to each other in the bit line direction BLD.

The second main cell region MAC2 may be disposed adjacent to the second dummy cell region DUC2 in the word line direction WLD. RMTJ layers may be disposed in the bit line direction BLD in the second main cell region MAC2.

DMTJ layers may be disposed in the cell edge region CBE of the second main cell region MAC2. A bit line BL may be disposed in the bit line direction BLD on the RMTJ layers and the DMTJ layers of the second memory cell region MAC2.

The memory cell region CB-3 may have a symmetric structure in the word line direction WLD with respect to the word line strap region WLS. Therefore, the second reference wiring region REL2 may correspond to (e.g., mirror) the first reference wiring region REL1. The second reference wiring line RL2-3 may correspond to the first reference wiring line RL1-3.

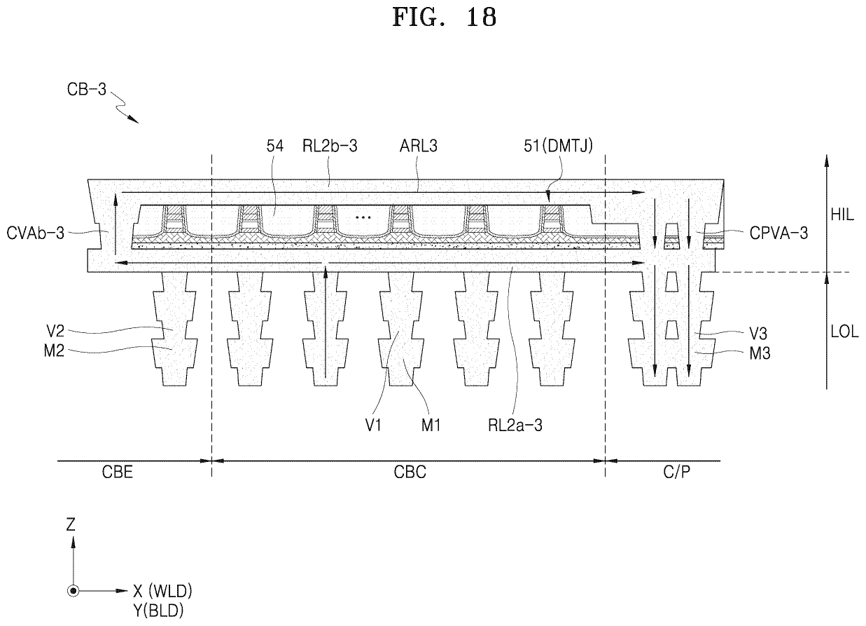

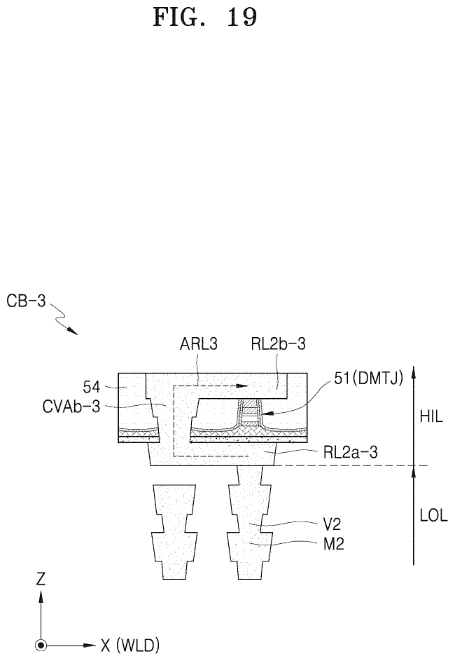

FIG. 18 is a main cross-sectional view in a word line direction and a bit line direction of FIG. 17, and FIG. 19 is a main cross-sectional view in the word line direction of FIG. 17.

In detail, FIG. 18 is a main cross-sectional view taken along line A3-B3-B3′ of FIG. 17. FIG. 19 is a main cross-sectional view taken along line A3-A3′ of FIG. 17. In FIGS. 18 and 19, the same reference numerals as FIGS. 12A, 12B, and 13 refer to like elements. In FIGS. 18 and 19, descriptions which are the same as or substantially similar to the descriptions of FIGS. 12A, 12B, and 13 may be briefly given or omitted.

As illustrated in FIG. 18, a memory cell region CB-3 may include a cell edge region CBE and a cell center region CBC. In FIG. 18, a core/peripheral circuit region C/P disposed at one side of the memory cell region CB-3 is further illustrated. FIG. 19 illustrates only the cell edge region CBE. The memory cell region CB-3 and the core/peripheral circuit region C/P may configure the variable resistance memory device VRM of FIG. 10.

The cell center region CBC may include a plurality of first wiring layers M1 and a plurality of first via layers V1. The cell edge region CBE may include a plurality of second wiring layers M2 and a plurality of second via layers V2. The core/peripheral circuit region C/P may include a plurality of third wiring layers M3 and a plurality of third via layers V3.

The first wiring layers M1, the first via layers V1, the second wiring layers M2, the second via layers V2, the third wiring layers M3, and the third via layers V3 may configure a lower wiring level layer LOL. The lower wiring level layer LOL may be insulated by a lower interlayer insulation layer.

A second lower reference wiring line RL2a-3 may be disposed on the lower wiring level layer LOL. The second lower reference wiring line RL2a-3 may be disposed in the same (or substantially similar) shape as the second reference wiring line RL2-3 of FIG. 17. The second lower reference wiring line RL2a-3 may be connected to the first via layers V1, the second via layers V2, and the third via layers V3.

A pad isolation insulation layer 38 and a plurality of dummy variable resistance pattern structures 51 may be disposed on the second lower reference wiring line RL2a-3 of the cell center region CBC and the cell edge region CBE. The dummy variable resistance pattern structures 51 may include DMTJ layers. A capping layer pattern 52 may be formed on a surface of the pad isolation insulation layer 38 to cover a sidewall of each of the dummy variable resistance pattern structures 51. A buried insulation layer pattern 54 filled between the dummy variable resistance pattern structures 51 may be formed on the capping layer pattern 52 and the pad isolation insulation layer 38.

A second cell via pattern CVAb-3 may be formed on the second lower reference wiring line RL2a-3 of the cell edge region CBE. The second cell via pattern CVAb-3 may be formed on a second lower reference wiring line RL2a-3 of one end of the cell edge region CBE which does not overlap the dummy variable resistance pattern structures 51. A first core/peripheral via pattern CPVA-3 may be formed on a second lower reference wiring line RL2a-3 of the core/peripheral circuit region C/P.

A second upper reference wiring line RL2b-3 may be disposed on the dummy variable resistance pattern structures 51 and the buried insulation layer pattern 54. The second upper reference wiring line RL2b-3 may be disposed in the same shape as the second reference wiring line RL2-3 of FIG. 17. The second lower reference wiring line RL2a-3 and the second upper reference wiring line RL2b-3 may correspond to the second reference wiring line RL2-3 of FIG. 7.

The second lower reference wiring line RL2a-3, the second cell via pattern CVAb-3, the first core/peripheral via pattern CPVA-3, and the second upper reference wiring line RL2b-3 may configure an upper wiring level layer HIL. The upper wiring level layer HIL may be insulated by the buried insulation layer pattern 54.

The second upper reference wiring line RL2b-3 may be connected to one end portion of the second lower reference wiring line RL2a-3 through the second cell via pattern CVAb-3, in the cell edge region CBE. The second upper reference wiring line RL2b-3 may be connected to the one end portion of the second lower reference wiring line RL2a-3 through the first core/peripheral via pattern CPVA-3, in the core/peripheral circuit region C/P.

In the memory cell region CB-3, as illustrated in FIGS. 18 and 19, a metal path ARL3 which does not pass through the DMTJ layers may be formed in a read operation of RMTJ layers disposed in the cell center region CBC. The metal path ARL3 may be a path which passes through the second lower reference wiring line RL2a-3, the second cell via pattern CVAb-3, and the second upper reference wiring line RL2b-3.

In FIG. 18, the metal path ARL3 may be a path which passes through the first wiring layers M1, the first via layers V1, the second lower reference wiring line RL2a-3, the second cell via pattern CVAb-3, the second upper reference wiring line RL2b-3, the first core/peripheral via pattern CPVA-3, the third wiring layers M3, and the third via layers V3.

The memory cell region CB-3 may include a second reference wiring line RL2-3 (e.g., the second upper reference wiring line RL2b-3) disposed in the same direction as the bit line BL by using the second cell via pattern CVAb-3 in a read operation of the RMTJ layers disposed in the cell center region CBC.

Therefore, a resistance and/or a capacitance of the second reference wiring line RL2-3 may be configured to be equal or substantially similar to the bit line BL (or a read wiring line). Accordingly, a read margin which is a difference between resistance values of the MTJ layers and a resistance value of the second reference wiring line RL2-3 in the memory cell region CB-3 may increase.

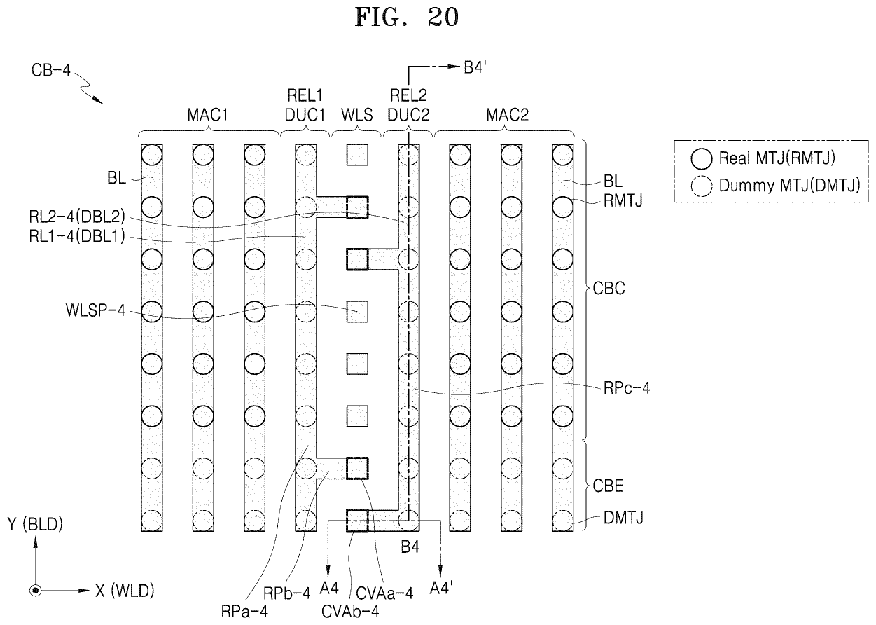

FIG. 20 is an enlarged plan view to describe a memory cell region of a variable resistance memory device according to at least one embodiment.

In detail, a memory cell region CB-4 may be an enlarged view of the edge portion EN1 of the memory cell region CB of FIG. 10. Except for that DMTJ layers are included in a cell center region CBC of each of a first main cell region MAC1 and a second main cell region MAC2, the memory cell region CB-4 may be the same as FIG. 11.

Except for the arrangement of a first dummy cell region DUC1, a first reference wiring region REL1, a word line strap region WLS, a second reference wiring region REL2, and a second dummy cell region DUC2 differs from FIG. 11, the memory cell region CB-4 may be the same as FIG. 11. In FIG. 20, the same reference numerals as FIG. 11 refer to like elements. In FIG. 20, description which is the same as or substantially similar to the description of FIG. 11 may be briefly given or omitted.

The memory cell region CB-4 may include a first main cell region MAC1, a first dummy cell region DUC1, a word line strap region WLS, a second dummy cell region DUC2, and a second main cell region MAC2 in a word line direction WLD. The first dummy cell region DUC1 may be a first reference wiring region REL1. The second dummy cell region DUC2 may be a second reference wiring region REL2. The memory cell region CB-4 may include a cell edge region CBE and a cell center region CBC in a bit line direction BLD.

RMTJ layers and DMTJ layers may be disposed in the bit line direction BLD in the first main cell region MAC1. RMTJ layers and DMTJ layers may be disposed in the cell center region CBC of the first main cell region MAC1. DMTJ layers may be disposed in the cell edge region CBE of the first main cell region MAC1. A bit line BL may be disposed in the bit line direction BLD on the RMTJ layers and the DMTJ layers of the first memory cell region MAC1.

The first dummy cell region DUC1 and the first reference wiring region REL1 may be disposed adjacent to the first main cell region MAC1 in the word line direction WLD. DMTJ layers may be disposed in the cell edge region CBE and the cell center region CBC, in the first dummy cell region DUC1 and the first reference wiring region REL1.

A first reference wiring line RL1-4 may be disposed in the bit line direction BLD on the DMTJ layers of the first dummy cell region DUC1 and the first reference wiring region REL1. The first reference wiring line RL1-4 may be a first dummy bit line DBL1. The first reference wiring line RL1-4, like the bit line BL, may be disposed in the bit line direction BLD.

The first reference wiring line RL1-4 may have a resistance and/or a capacitance which is equal or substantially similar to that of the bit line BL, in a read operation of the RMTJ layers. The first reference wiring line RL1-4 may include a first reference wiring pattern RPa-4 disposed on and under the DMTJ layers and a first reference extension wiring pattern RPb-4 extending in the word line direction WLD from the first reference wiring pattern RPa-4.

The first reference extension wiring pattern RPb-4 may be disposed in the cell edge region CBE and the cell center region CBC. In some embodiments, the first reference extension wiring pattern RPb-4 may be disposed in only the cell center region CBC. The first reference extension wiring pattern RPb-4 may be disposed on only some of upper portions and lower portions of DMTJ layers disposed in the cell edge region CBE and the cell center region CBC.

The word line strap region WLS may be disposed adjacent to the first reference wiring region REL1 in the word line direction WLD. The word line strap region WLS may include a plurality of word line strap patterns WLSP-4. The word line strap patterns WLSP-4 may be disposed apart from one another in the bit line direction BLD.

The word line strap patterns WLSP-4 may include a first cell via pattern CVAa-4 connected to the first reference extension wiring pattern RPb-4. The word line strap region WLS may include a first cell via pattern CVAa-4 connected to the first reference wiring line RL1-4, namely, the first reference extension wiring pattern RPb-4. The first cell via pattern CVAa-4, as described below, may be connected to first wiring layers M1, first via layers V1, second wiring layers M2, and second via layers V2 of the cell edge region CBE and the cell center region CBC.

The second dummy cell region DUC2 and the second reference wiring region REL2 may be disposed adjacent to the word line strap region WLS in the word line direction WLD. DMTJ layers may be disposed in the cell edge region CBE and the cell center region CBC, in the second dummy cell region DUC2 and the second reference wiring region REL2.

A second reference wiring line RL2-4 may be disposed in the bit line direction BLD on the DMTJ layers of the second dummy cell region DUC2 and the second reference wiring region REL2. The second reference wiring line RL2-4 may be a second dummy bit line DBL2.

The second reference wiring line RL2-4, like the bit line BL, may be disposed in the bit line direction BLD. The second reference wiring line RL2-4 may have a resistance and/or a capacitance which is equal or substantially similar to that of the bit line BL, in a read operation of the RMTJ layers. The second reference wiring line RL2-4 may include a second reference wiring pattern RPc-4 disposed on and under the DMTJ layers and a second reference extension wiring pattern RPd-4 extending in the word line direction WLD from the second reference wiring pattern RPc-4.

The second reference extension wiring pattern RPd-4 may be disposed in the cell edge region CBE and the cell center region CBC. The second reference extension wiring pattern RPd-4 may be disposed on only some of upper portions and lower portions of DMTJ layers disposed in the cell edge region CBE and the cell center region CBC.

The word line strap region WLS may include a second cell via pattern CVAb-4 connected to the second reference wiring line RL2-4, namely, the second reference extension wiring pattern RPd-4. The second cell via pattern CVAb-4, as described below, may be connected to first wiring layers M1, first via layers V1, second wiring layers M2, and second via layers V2 of the cell edge region CBE and the cell center region CBC.

The first cell via pattern CVAa-4 and the second cell via pattern CVAb-4 may be disposed in the cell center region CBC and the cell edge region CBE. The first cell via pattern CVAa-4 and the second cell via pattern CVAb-4 may be disposed adjacent to each other in the bit line direction BLD.

The second main cell region MAC2 may be disposed adjacent to the second dummy cell region DUC2 in the word line direction WLD. RMTJ layers and DMTJ layers may be disposed in the bit line direction BLD in the second main cell region MAC2. DMTJ layers may be disposed in the cell edge region CBE of the second main cell region MAC2.

RMTJ layers and DMTJ layers may be disposed in the cell center region CBC of the second main cell region MAC2. A bit line BL may be disposed in the bit line direction BLD on the RMTJ layers and the DMTJ layers of the second memory cell region MAC2.

The memory cell region CB-4 may have a symmetric structure in the word line direction WLD with respect to the word line strap region WLS. Therefore, the second reference wiring region REL2 may correspond to the first reference wiring region REL1. The second reference wiring line RL2-4 may correspond to the first reference wiring line RL1-4.

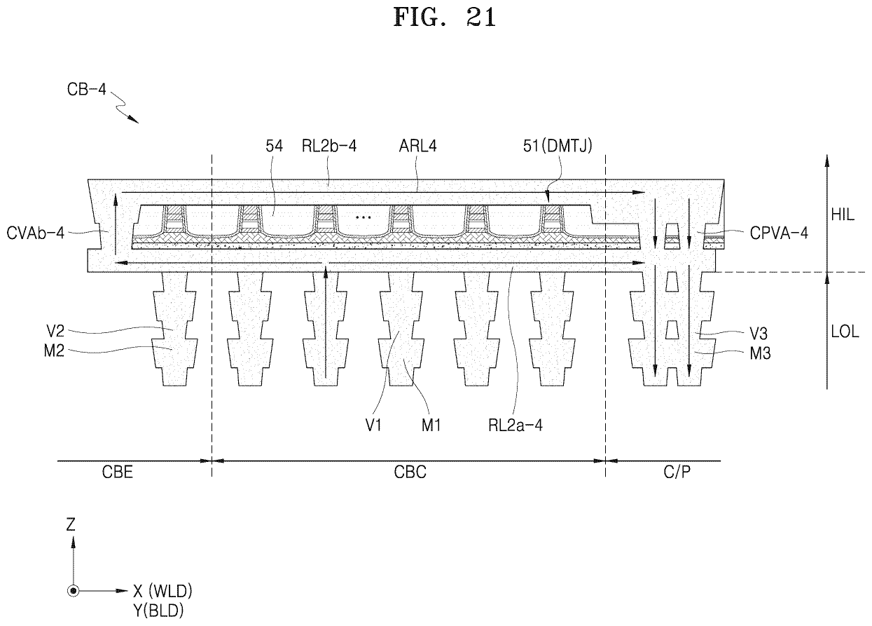

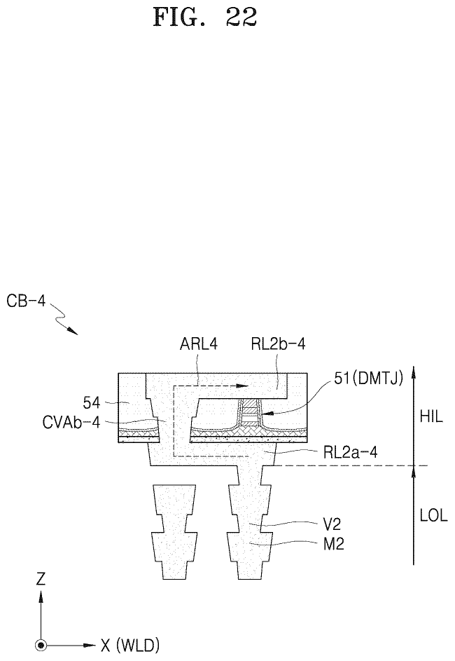

FIG. 21 is a main cross-sectional view in a word line direction and a bit line direction of FIG. 20. and FIG. 22 is a main cross-sectional view in the word line direction of FIG. 20.

In detail, FIG. 21 is a main cross-sectional view taken along line A4-B4-B4′ of FIG. 20. FIG. 22 is a main cross-sectional view taken along line A4-A4′ of FIG. 20. In FIGS. 21 and 22, the same reference numerals as FIGS. 12A, 12B, and 13 refer to like elements. In FIGS. 21 and 22, descriptions which are the same as or substantially similar to the descriptions of FIGS. 12A, 12B, and 13 may be briefly given or omitted.

As illustrated in FIG. 21, a memory cell region CB-4 may include a cell edge region CBE and a cell center region CBC. In FIG. 21, a core/peripheral circuit region C/P disposed at one side of the memory cell region CB-4 is further illustrated. FIG. 22 illustrates only the cell edge region CBE. The memory cell region CB-4 and the core/peripheral circuit region C/P may configure the variable resistance memory device VRM of FIG. 10.

The cell center region CBC may include a plurality of first wiring layers M1 and a plurality of first via layers V1. The cell edge region CBE may include a plurality of second wiring layers M2 and a plurality of second via layers V2. The core/peripheral circuit region C/P may include a plurality of third wiring layers M3 and a plurality of third via layers V3.

The first wiring layers M1, the first via layers V1, the second wiring layers M2, the second via layers V2, the third wiring layers M3, and the third via layers V3 may configure a lower wiring level layer LOL. The lower wiring level layer LOL may be insulated by a lower interlayer insulation layer.

A second lower reference wiring line RL2a-4 may be disposed on the lower wiring level layer LOL. The second lower reference wiring line RL2a-4 may be disposed in the same shape as the second reference wiring line RL2-4 of FIG. 20. The second lower reference wiring line RL2a-4 may be connected to the first via layers V1, the second via layers V2, and the third via layers V3.

A pad isolation insulation layer 38 and a plurality of dummy variable resistance pattern structures 51 may be disposed on the second lower reference wiring line RL2a-4 of the cell center region CBC and the cell edge region CBE. The dummy variable resistance pattern structures 51 may include DMTJ layers. A capping layer pattern 52 may be formed on a surface of the pad isolation insulation layer 38 to cover a sidewall of each of the dummy variable resistance pattern structures 51. A buried insulation layer pattern 54 filled between the dummy variable resistance pattern structures 51 may be formed on the capping layer pattern 52 and the pad isolation insulation layer 38.

A second cell via pattern CVAb-4 may be formed on the second lower reference wiring line RL2a-4 of the cell edge region CBE. The second cell via pattern CVAb-4 may be formed on a second lower reference wiring line RL2a-4 of one end of the cell edge region CBE which does not overlap the dummy variable resistance pattern structures 51. A first core/peripheral via pattern CPVA-4 may be formed on a second lower reference wiring line RL2a-4 of the core/peripheral circuit region C/P.

A second upper reference wiring line RL2b-4 may be disposed on the dummy variable resistance pattern structures 51 and the buried insulation layer pattern 54. The second upper reference wiring line RL2b-4 may be disposed in the same shape as the second reference wiring line RL2-4 of FIG. 20. The second lower reference wiring line RL2a-4 and the second upper reference wiring line RL2b-4 may correspond to the second reference wiring line RL2-4 of FIG. 20.

The second lower reference wiring line RL2a-4, the second cell via pattern CVAb-4, the first core/peripheral via pattern CPVA-4, and the second upper reference wiring line RL2b-4 may configure an upper wiring level layer HIL. The upper wiring level layer HIL may be insulated by the buried insulation layer pattern 54.

The second upper reference wiring line RL2b-4 may be connected to one end portion of the second lower reference wiring line RL2a-4 through the second cell via pattern CVAb-4, in the cell edge region CBE. The second upper reference wiring line RL2b-4 may be connected to the one end portion of the second lower reference wiring line RL2a-4 through the first core/peripheral via pattern CPVA-4, in the core/peripheral circuit region C/P.

In the memory cell region CB-4, as illustrated in FIGS. 21 and 22, a metal path ARL4 which does not pass through the DMTJ layers may be formed in a read operation of RMTJ layers disposed in the cell center region CBC. The metal path ARL4 may be a path which passes through the second lower reference wiring line RL2a-4, the second cell via pattern CVAb-4, and the second upper reference wiring line RL2b-4.

In FIG. 21, the metal path ARL4 may be a path which passes through the first wiring layers M1, the first via layers V1, the second lower reference wiring line RL2a-4, the second cell via pattern CVAb-4, the second upper reference wiring line RL2b-4, the first core/peripheral via pattern CPVA-4, the third wiring layers M3, and the third via layers V3.

The memory cell region CB-4 may include a second reference wiring line RL2-4 (e.g., the second upper reference wiring line RL2b-4) disposed in the same direction as the bit line BL by using the second cell via pattern CVAb-4 in a read operation of the RMTJ layers disposed in the cell center region CBC. Therefore, a resistance and/or a capacitance of the second reference wiring line RL2-4 may be configured to be equal or substantially similar to the bit line BL (or a read wiring line). Accordingly, a read margin which is a difference between resistance values of the MTJ layers and a resistance value of the second reference wiring line RL2-4 in the memory cell region CB-4 may increase.

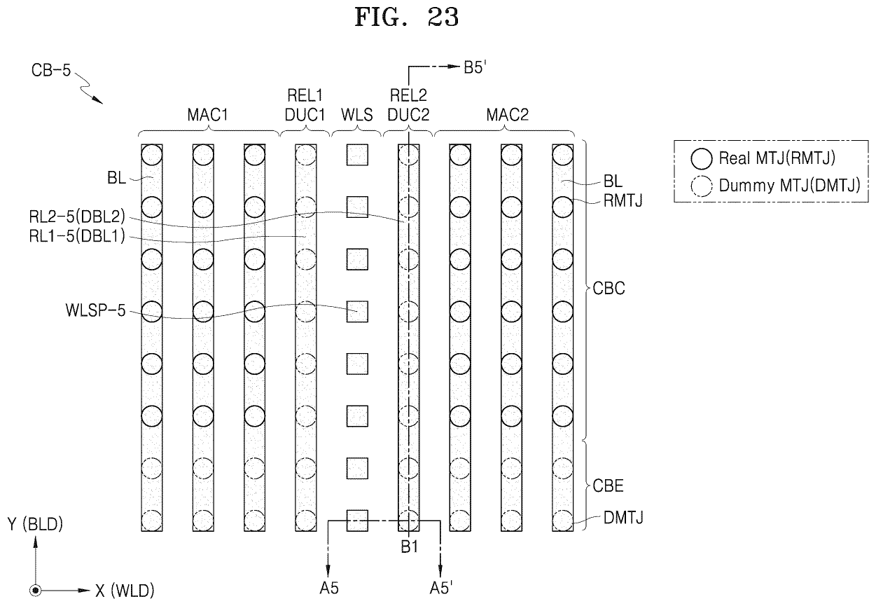

FIG. 23 is an enlarged plan view to describe a memory cell region of a variable resistance memory device according to at least one embodiment.

In detail, a memory cell region CB-5 may be an enlarged view of the edge portion EN1 of the memory cell region CB of FIG. 10. Except for the arrangement of a first dummy cell region DUC1, a first reference wiring region REL1, a word line strap region WLS, a second reference wiring region REL2, and a second dummy cell region DUC2 differs from FIG. 11, the memory cell region CB-5 may be the same as FIG. 11. In FIG. 23, the same reference numerals as FIG. 11 refer to like elements. In FIG. 23, description which is the same as or substantially similar to the description of FIG. 11 may be briefly given or omitted.

The memory cell region CB-5 may include a first main cell region MAC1, a first dummy cell region DUC1, a word line strap region WLS, a second dummy cell region DUC2, and a second main cell region MAC2 in a word line direction WLD. The first dummy cell region DUC1 may be a first reference wiring region REL1. The second dummy cell region DUC2 may be a second reference wiring region REL2. The memory cell region CB-5 may include a cell edge region CBE and a cell center region CBC in a bit line direction BLD.

RMTJ layers and DMTJ layers may be disposed in the bit line direction BLD in the first main cell region MAC1. RMTJ layers may be disposed in the cell center region CBC of the first main cell region MAC1. DMTJ layers may be disposed in the cell edge region CBE of the first main cell region MAC1. A bit line BL may be disposed in the bit line direction BLD on the RMTJ layers and the DMTJ layers of the first memory cell region MAC1.

The first dummy cell region DUC1 and the first reference wiring region REL1 may be disposed adjacent to the first main cell region MAC1 in the word line direction WLD. DMTJ layers may be disposed in the cell edge region CBE and the cell center region CBC, in the first dummy cell region DUC1 and the first reference wiring region REL1.

A first reference wiring line RL1-5 may be disposed in the bit line direction BLD on the DMTJ layers of the first dummy cell region DUC1 and the first reference wiring region REL1. A first dummy bit line DBL1 may be disposed on the first reference wiring line RL1-5. The first reference wiring line RL1-5, like the bit line BL, may be disposed in the bit line direction BLD.

The first reference wiring line RL1-5 may have a resistance and/or a capacitance which is equal or substantially similar to that of the bit line BL, in a read operation of the RMTJ layers. DMTJ layers may be disposed under the first reference wiring line RL1-5.

The word line strap region WLS may be disposed adjacent to the first dummy cell region DUC1 and the first reference wiring region REL1 in the word line direction WLD. The word line strap region WLS may include a plurality of word line strap patterns WLSP-5. The word line strap patterns WLSP-5 may be disposed apart from one another in the bit line direction BLD.

The second dummy cell region DUC2 and the second reference wiring region REL2 may be disposed adjacent to the word line strap region WLS in the word line direction WLD. DMTJ layers may be disposed in the cell edge region CBE and the cell center region CBC, in the second dummy cell region DUC2 and the second reference wiring region REL2.

A second reference wiring line RL2-5 may be disposed in the bit line direction BLD on the DMTJ layers of the second dummy cell region DUC2 and the second reference wiring region REL2. A second dummy bit line DBL2 may be disposed on the second reference wiring line RL2-5.

The second reference wiring line RL2-5, like the bit line BL, may be disposed in the bit line direction BLD. The second reference wiring line RL2-5 may have a resistance and/or a capacitance which is equal or substantially similar to that of the bit line BL, in a read operation of the RMTJ layers.

The second main cell region MAC2 may be disposed adjacent to the second dummy cell region DUC2 in the word line direction WLD. RMTJ layers and DMTJ layers may be disposed in the bit line direction BLD in the second main cell region MAC2. DMTJ layers may be disposed in the cell edge region CBE of the second main cell region MAC2.

RMTJ layers may be disposed in a cell center region CBC of the second main cell region MAC2. A bit line BL may be disposed in the bit line direction BLD on the RMTJ layers and the DMTJ layers of the second memory cell region MAC2.

The memory cell region CB-5 may have a symmetric structure in the word line direction WLD with respect to the word line strap region WLS. Therefore, the second reference wiring region REL2 may correspond to the first reference wiring region REL1. The second reference wiring line RL2-5 may correspond to the first reference wiring line RL1-5.

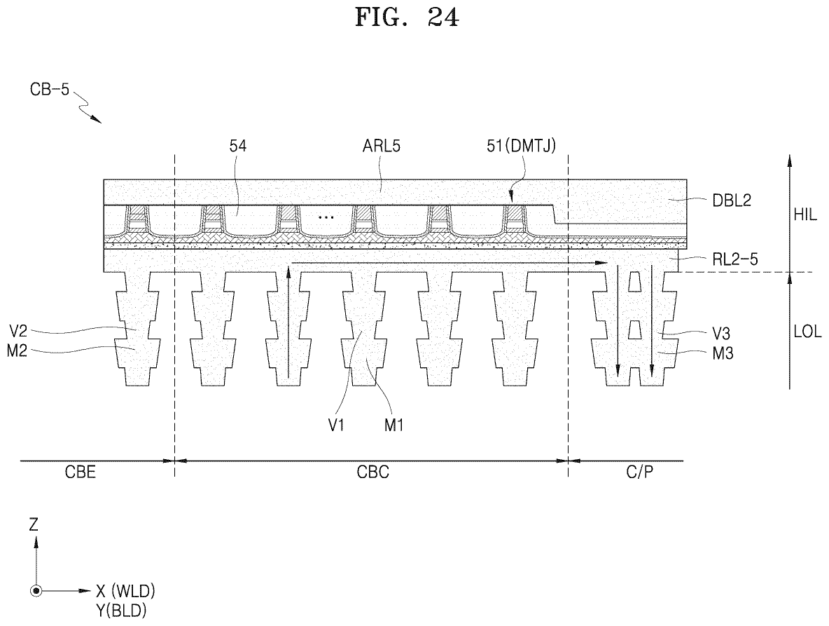

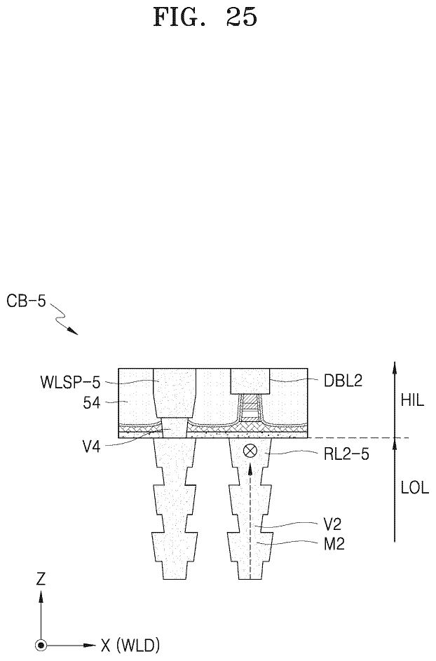

FIG. 24 is a main cross-sectional view in the bit line direction of FIG. 23, and FIG. 25 is a main cross-sectional view in the word line direction of FIG. 23.

In detail, FIG. 24 is a main cross-sectional view taken along line B5-B5′ of FIG. 23. FIG. 25 is a main cross-sectional view taken along line A5-A5′ of FIG. 23. In FIGS. 24 and 25, the same reference numerals as FIGS. 12A, 12B, and 13 refer to like elements. In FIGS. 24 and 25, descriptions which are the same as or substantially similar to the descriptions of FIGS. 12A, 12B, and 13 may be briefly given or omitted.

As illustrated in FIG. 24, a memory cell region CB-5 may include a cell edge region CBE and a cell center region CBC. In FIG. 24, a core/peripheral circuit region C/P disposed at one side of the memory cell region CB-5 is further illustrated. FIG. 25 illustrates only the cell edge region CBE. The memory cell region CB-5 and the core/peripheral circuit region C/P may configure the variable resistance memory device VRM of FIG. 10.

The cell center region CBC may include a plurality of first wiring layers M1 and a plurality of first via layers V1. The cell edge region CBE may include a plurality of second wiring layers M2 and a plurality of second via layers V2. The core/peripheral circuit region C/P may include a plurality of third wiring layers M3 and a plurality of third via layers V3.

The first wiring layers M1, the first via layers V1, the second wiring layers M2, the second via layers V2, the third wiring layers M3, and the third via layers V3 may configure a lower wiring level layer LOL. The lower wiring level layer LOL may be insulated by a lower interlayer insulation layer.

A second reference wiring line RL2-5 may be disposed on the lower wiring level layer LOL. The second reference wiring line RL2-5 may be disposed in the same shape as the second reference wiring line RL2-5 of FIG. 23. The second reference wiring line RL2-5 may be connected to the first via layers V1, the second via layers V2, and the third via layers V3.

A pad isolation insulation layer 38 and a plurality of variable resistance pattern structures 51 may be disposed on the second reference wiring line RL2-5 of the cell center region CBC and the cell edge region CBE. The variable resistance pattern structures 51 may include DMTJ layers. A capping layer pattern 52 may be formed on a surface of the pad isolation insulation layer 38 to cover a sidewall of each of the variable resistance pattern structures 51. A buried insulation layer pattern 54 filled between the variable resistance pattern structures 51 may be formed on the capping layer pattern 52 and the pad isolation insulation layer 38.

A second dummy bit line DBL2 may be disposed on the variable resistance pattern structures 51 and the buried insulation layer pattern 54. The second reference wiring line RL2-5 and the second dummy bit line DBL2 may configure an upper wiring level layer HIL. The upper wiring level layer HIL may be insulated by the buried insulation layer pattern 54.

In the memory cell region CB-5, as illustrated in FIGS. 24 and 25, a metal path ARL4 which does not pass through the DMTJ layers may be formed in a read operation of RMTJ layers disposed in the cell center region CBC. In FIG. 24, the metal path ARL5 may be a path which passes through the first wiring layers M1, the first via layers V1, the second reference wiring line RL2-5, the third wiring layers M3, and the third via layers V3.

In the cell edge region CBE of FIG. 25, the metal path ARL5 may be a path which passes through the second wiring layers M2, the second via layers V2, and the second lower reference wiring line RL2-5. In the cell edge region CBE of FIG. 25, a fourth via layer V4 connected to word line strap patterns WLSP-5 may be disposed.

The memory cell region CB-5 may include a second reference wiring line RL2-5 disposed in the same direction as the bit line BL in a read operation of the RMTJ layers disposed in the cell center region CBC. Therefore, a resistance and/or a capacitance of the second reference wiring line RL2-5 may be configured to be equal or substantially similar to the bit line BL (or a read wiring line). Accordingly, a read margin which is a difference between resistance values of the MTJ layers and a resistance value of the second reference wiring line RL2-4 in the memory cell region CB-5 may increase.

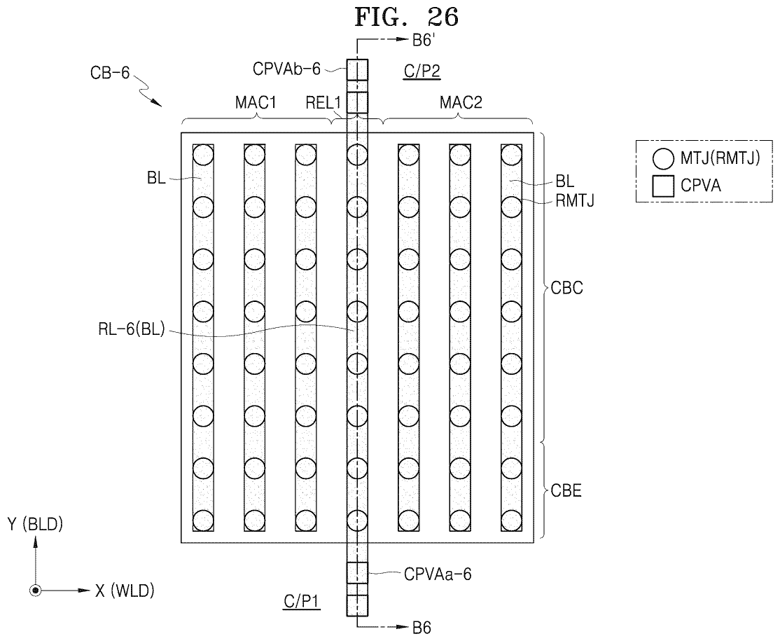

FIG. 26 is an enlarged plan view to describe a memory cell region of a variable resistance memory device according to at least one embodiment.

In detail, a memory cell region CB-6 may be an enlarged view of the edge portion EN1 of the memory cell region CB of FIG. 10. Except for that the memory cell region CB-6 does not include a dummy cell region and a word line strap region, the memory cell region CB-6 may be the same as FIG. 11.

Except for that the memory cell region CB-6 includes a reference wiring line RL-6 extending to a core/peripheral circuit region C/P, the memory cell region CB-6 may be the same as FIG. 11. In FIG. 26, the same reference numerals as FIG. 11 refer to like elements. In FIG. 26, description which is the same as or substantially similar to the description of FIG. 11 may be briefly given or omitted.

The memory cell region CB-6 may include a first main cell region MAC1, a first reference wiring region REL1, and a second main cell region MAC2 in a word line direction WLD. The memory cell region CB-6 may include a cell edge region CBE and a cell center region CBC in a bit line direction BLD.

RMTJ layers may be disposed in the bit line direction BLD in the first main cell region MAC1. RMTJ layers may be disposed in a cell edge region CBE and a cell center region CBC of the first main cell region MAC1. A bit line BL may be disposed in the bit line direction BLD on the RMTJ layers of the first memory cell region MAC1.

The first reference wiring region REL1 may be disposed adjacent to the first memory cell region MAC1 in the word line direction WLD. RMTJ layers may be disposed in a cell edge region CBE and a cell center region CBC of the first reference wiring region REL1. The RMTJ layers may be disposed in the bit line direction BLD in the first reference wiring region REL1.

A reference wiring line RL-6 may be disposed in the bit line direction BLD on and under the RMTJ layers of the first reference wiring line REL1. The reference wiring line RL-6 may be disposed in the cell edge region CBE and the cell center region CBC. The reference wiring line RL-6, like the bit line BL, may be disposed in the bit line direction BLD. The reference wiring line RL-6 may include a bit line BL.

The reference wiring line RL-6 may extend to first and second core/peripheral circuit regions C/P1 and C/P2. The reference wiring line RL-6 may extend to the first and second core/peripheral circuit regions C/P1 and C/P2 disposed on and under the memory cell region CB-6. The reference wiring line RL-6 may extend to a first core/peripheral via pattern CPVAa-6 disposed in the first core/peripheral circuit region C/P1 under the memory cell region CB-6.

The reference wiring line RL-6 may extend to a second core/peripheral via pattern CPVAb-6 disposed in the second core/peripheral circuit region C/P2 under the memory cell region CB-6. The reference wiring line RL-6 may have a resistance and/or a capacitance which is equal or substantially similar to that of the bit line BL, in a read operation of the RMTJ layers.

The second main cell region MAC2 may be disposed adjacent to the first reference wiring region REL1 in the word line direction WLD. RMTJ layers may be disposed in the bit line direction BLD in the second main cell region MAC2. RMTJ layers may be disposed in a cell edge region CBE and a cell center region CBC of the second main cell region MAC2. A bit line BL may be disposed in the bit line direction BLD on the RMTJ layers of the second memory cell region MAC2.

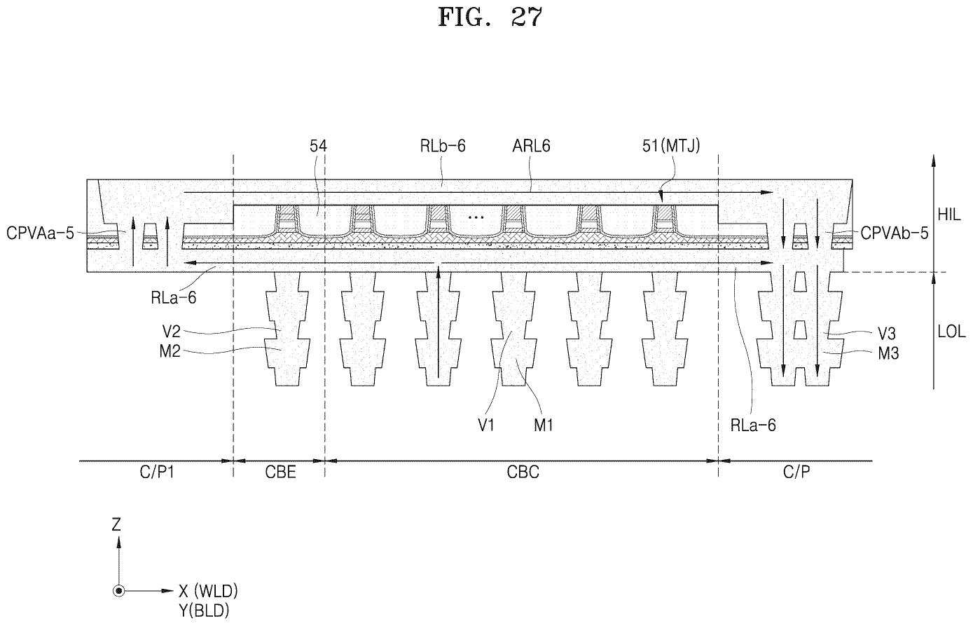

FIG. 27 is a main cross-sectional view in the bit line direction of FIG. 26.

In detail, FIG. 27 is a main cross-sectional view taken along line B6-B6′ of FIG. 26. In FIG. 27, the same reference numerals as FIGS. 12A, 12B, and 13 refer to like elements. In FIG. 27, descriptions which are the same as or substantially similar to the descriptions of FIGS. 12A, 12B, and 13 may be briefly given or omitted.

The memory cell region CB-6 may include a cell edge region CBE and a cell center region CBC. First and second core/peripheral circuit regions C/P1 and C/P2 may be respectively disposed at both sides of the memory cell region CB-6. The memory cell region CB-6 and the first and second core/peripheral circuit regions C/P1 and C/P2 may configure the variable resistance memory device VRM of FIG. 10.

The cell center region CBC may include a plurality of first wiring layers M1 and a plurality of first via layers V1. The cell edge region CBE may include a plurality of second wiring layers M2 and a plurality of second via layers V2. The second core/peripheral circuit region C/P2 may include a plurality of third wiring layers M3 and a plurality of third via layers V3.

The first wiring layers M1, the first via layers V1, the second wiring layers M2, the second via layers V2, the third wiring layers M3, and the third via layers V3 may configure a lower wiring level layer LOL. The lower wiring level layer LOL may be insulated by a lower interlayer insulation layer.

A first lower reference wiring line RLa-6 may be disposed on the lower wiring level layer LOL. The first lower reference wiring line RLa-6 may be disposed in the same shape as the first reference wiring line RL-6 of FIG. 27. The first lower reference wiring line RLa-6 may be connected to the first via layers V1, the second via layers V2, and the third via layers V3.

A pad isolation insulation layer 38 and a plurality of variable resistance pattern structures 51 may be disposed on the first lower reference wiring line RLa-6 of the cell center region CBC and the cell edge region CBE. The variable resistance pattern structures 51 may include RMTJ layers. A capping layer pattern 52 may be formed on a surface of the pad isolation insulation layer 38 to cover a sidewall of each of the variable resistance pattern structures 51. A buried insulation layer pattern 54 filled between the variable resistance pattern structures 51 may be formed on the capping layer pattern 52 and the pad isolation insulation layer 38.

A first core/peripheral via pattern CPVAa-6 may be formed on a first lower reference wiring line RLa-6 of the first core/peripheral circuit region C/P1. The first core/peripheral via pattern CPVAa-6 may be formed on the first lower reference wiring line RLa-6 of one end of the first core/peripheral circuit region C/P1 which does not overlap the variable resistance pattern structures 51.

A second core/peripheral via pattern CPVAb-6 may be formed on a first lower reference wiring line RLa-6 of the second core/peripheral circuit region C/P2. The second core/peripheral via pattern CPVAb-6 may be formed on the first lower reference wiring line RLa-6 of one end of the second core/peripheral circuit region C/P2 which does not overlap the variable resistance pattern structures 51.

A first upper reference wiring line RLb-6 may be disposed on the variable resistance pattern structures 51, the buried insulation layer pattern 54, the first core/peripheral circuit region C/P1, and the second core/peripheral circuit region C/P2. The first upper reference wiring line RLb-6 may be disposed in the same shape as the first reference wiring line RL-6 of FIG. 26. The first lower reference wiring line RLa-6 and the first upper reference wiring line RLb-6 may correspond to the first reference wiring line RL-6 of FIG. 26.

The first lower reference wiring line RLa-6, the first core/peripheral via pattern CPVAa-6, the second core/peripheral via pattern CPVAb-6, and the first upper reference wiring line RLb-6 may configure an upper wiring level layer HIL. The upper wiring level layer HIL may be insulated by the buried insulation layer pattern 54.

The first upper reference wiring line RLb-6 may be connected to one end portion of the first lower reference wiring line RLa-6 through the first core/peripheral via pattern CPVAa-6, in the first core/peripheral circuit region C/P1. The first upper reference wiring line RLb-6 may be connected to one end portion of the first lower reference wiring line RLa-6 through the second core/peripheral via pattern CPVAb-6, in the second core/peripheral circuit region C/P2.

In the memory cell region CB-6, as illustrated in FIG. 27, a metal path ARL6 which does not pass through RMTJ layers may be formed in a read operation of the RMTJ layers disposed in the cell center region CBC. The metal path ARL6 may be a path which passes through the first lower reference wiring line RLa-6, the first core/peripheral via pattern CPVAa-6, and the first upper reference wiring line RLb-6.

The metal path ARL6 may be a path which passes through the first wiring layers M1, the first via layers V1, the first lower reference wiring line RLa-6, the first core/peripheral via pattern CPVAa-6, the first upper reference wiring line RLb-6, the second core/peripheral via pattern CPVAb-6, the third wiring layers M3, and the third via layers V3.

The memory cell region CB-6 may include a first reference wiring line RL-6 (e.g., the first upper reference wiring line RLb-6) disposed in the same direction as the bit line BL by using the first core/peripheral via pattern CPVAa-6 and the second core/peripheral via pattern CPVAb-6 in a read operation of the RMTJ layers disposed in the cell center region CBC.

Therefore, a resistance and/or a capacitance of the reference wiring line RL-6 may be configured to be equal or substantially similar to the bit line BL (or a read wiring line). Accordingly, a read margin which is a difference between resistance values of the MTJ layers and a resistance value of the reference wiring line RL-6 in the memory cell region CB-6 may increase.

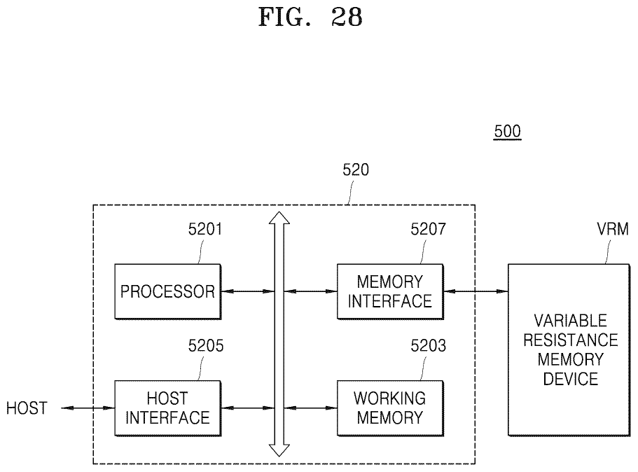

FIG. 28 is a configuration diagram of a data processing system 500 including a variable resistance memory device VRM according to at least one embodiment.

In detail, the data processing system 500 may include a memory controller 520 connected between a host and the variable resistance memory device VRM. The memory controller 520 may be configured to access the variable resistance memory device VRM in response to a request of the host. The memory controller 520 may include a processor 5201, a working memory 5203, a host interface 5205, and a memory interface 5207.

The processor 5201 may be configured to control an overall operation of the memory controller 520, and the working memory 5203 may store an application, data, and instructions for control signals for an operation of the memory controller 520. The host interface 5205 may perform protocol conversion for data/control signal exchange between the host and the memory controller 520.

The memory interface 5207 may be configured to perform protocol conversion for data/control signal exchange between the memory controller 520 and the variable resistance memory device VRM. The variable resistance memory device VRM may be as described above, and thus, its description is omitted. The data processing system 500 according to at least one embodiment may be a memory card, but is not limited thereto.

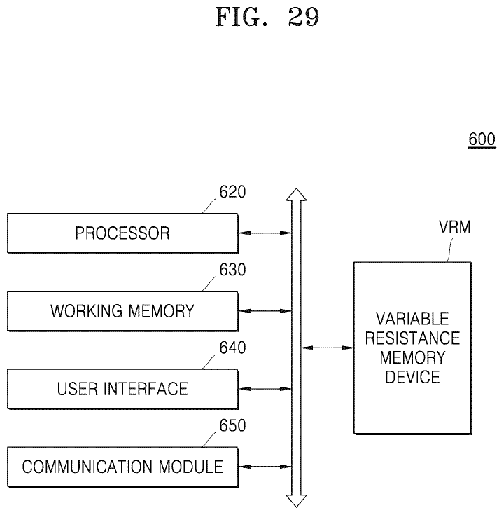

FIG. 29 is a configuration diagram of a data processing system 600 including a variable resistance memory device according to at least one embodiment.

In detail, the data processing system 600 may include a variable resistance memory device VRM, a processor 620, a working memory 630, and a user interface 640, and depending on the case, the data processing system 600 may further include a communication module 650. The processor 620 may be a central processing unit (CPU).

The working memory 630 may store an application program, data, and instructions for control signals for an operation of the data processing system 600. The user interface 640 may provide an environment which enables a user to access the data processing system 600 and may provide the user with a data processing process and result of the data processing system 600.

The variable resistance memory device VRM may be as described above, and thus, its description is omitted. The data processing system 600 may be used as a disk device, or may be used as an internal/external memory card of a portable electronic device, or may be used as an image processor and the other application chipset.

Hereinabove, examples embodiments have been described in the drawings and the specification. Embodiments have been described by using the terms described herein, but this has been merely used for describing the inventive concepts and has not been used for limiting a meaning or limiting the scope of the inventive concepts defined in the following claims. Therefore, it may be understood by those of ordinary skill in the art that various modifications and other equivalent embodiments may be implemented from the inventive concepts. Accordingly, the spirit and scope of the inventive concepts may be defined based on the spirit and scope of the following claims.

While the inventive concepts have been particularly shown and described with reference to embodiments thereof, it will be understood that various changes in form and details may be made therein without departing from the spirit and scope of the following claims.

What is claimed is:

1. A variable resistance memory device comprising:
a memory cell region including a main cell region, a dummy cell region, a reference wiring region, and a word line strap region,
wherein the memory cell region comprises
a plurality of word lines extending in a first direction and spaced apart from one another in a second direction perpendicular to the first direction,
a plurality of bit lines on the plurality of word lines, the plurality of bit lines extending in the second direction and spaced apart from one another in the first direction, and
a plurality of memory cells each including a real magnetic tunnel junction (MTJ) layer in a first intersection region between one of the plurality of word lines and a corresponding one of the plurality of bit lines,
wherein the dummy cell region comprises
a plurality of dummy bit lines on the plurality of word lines and extending in the second direction such that at least one of a resistance or capacitance of the plurality of dummy bit lines is equal to the plurality of bit lines, and
a plurality of dummy memory cells each including a dummy MTJ layer in a second intersection region between one of the plurality of word lines and a corresponding dummy bit line of the plurality of dummy bit lines,
wherein the word line strap region comprises a plurality of word line strap patterns spaced apart from one another in the second direction,
wherein the dummy cell region and the reference wiring region comprise a plurality of reference wiring lines configured as a reference resistor in a read operation of the plurality of memory cells, and
wherein the plurality of reference wiring lines include the plurality of dummy bit lines.

2. The variable resistance memory device of claim 1, wherein
the dummy cell region and the reference wiring region are a same region,
the plurality of reference wiring lines comprise
reference wiring patterns spaced apart in the second direction, and
reference extension wiring patterns connected to the reference wiring patterns and extending in the first direction, and
the plurality of word line strap patterns includes cell via patterns connected to the reference extension wiring patterns.

3. The variable resistance memory device of claim 2, wherein
the memory cell region comprises a cell center region and a cell edge region at an edge portion of the cell center region, and
the reference extension wiring patterns are in the cell edge region.

4. The variable resistance memory device of claim 2, wherein
the memory cell region comprises a cell center region and a cell edge region at an edge portion of the cell center region, and the reference extension wiring patterns are in the cell center region and the cell edge region.

5. The variable resistance memory device of claim 2, wherein
the reference wiring patterns comprise lower reference wiring patterns under the dummy MTJ layer and upper reference wiring patterns over the dummy MTJ layer, and
the lower reference wiring patterns and the upper reference wiring patterns are connected to the cell via patterns.

6. The variable resistance memory device of claim 5, further comprising:
a core/peripheral circuit region disposed at a perimeter of the memory cell region,
wherein the core/peripheral circuit region comprises core/peripheral via patterns connecting the lower reference wiring patterns to the upper reference wiring patterns.

7. The variable resistance memory device of claim 1, wherein
the reference wiring region is spaced apart from and adjacent to the dummy cell region,
the plurality of reference wiring lines comprise
reference wiring patterns spaced from each other in the second direction, and
reference extension wiring patterns connected to the reference wiring patterns and extending in the first direction, and
the reference wiring region includes cell via patterns connected to the reference extension wiring patterns.

8. The variable resistance memory device of claim 7, wherein
the memory cell region comprises a cell center region and a cell edge region at an edge portion of the cell center region, and
the reference extension wiring patterns are in the cell center region and the cell edge region.

9. The variable resistance memory device of claim 7, wherein
the reference wiring patterns comprise lower reference wiring patterns under the dummy MTJ layer and upper reference wiring patterns over the dummy MTJ layer, and
the lower reference wiring patterns and the upper reference wiring patterns are connected to the cell via patterns.

10. The variable resistance memory device of claim 9, further comprising:
a core/peripheral circuit region at a perimeter of the memory cell region,
wherein the core/peripheral circuit region comprises core/peripheral via patterns connecting the lower reference wiring patterns to the upper reference wiring patterns.

11. The variable resistance memory device of claim 1, wherein
the main cell region comprises a plurality of main cell regions spaced apart from one another in the first direction,
the dummy cell region comprises a plurality of dummy cell regions adjacent to the plurality of main cell regions, and
the word line strap region is between the plurality of dummy cell regions in the first direction.

12. A variable resistance memory device comprising:
a memory cell region; and
a core/peripheral circuit region at a perimeter of the memory cell region,
wherein the memory cell region comprises
a cell center region,
a cell edge region at an edge portion of the cell center region,
a dummy cell region adjacent to a main cell region,
a word line strap region adjacent to the dummy cell region, and
a plurality of word lines extending in a first direction and spaced apart from one another in a second direction perpendicular to the first direction,
wherein the main cell region comprises
a plurality of bit lines on the plurality of word lines, the plurality of bit lines extending in the second direction and spaced apart from one another in the first direction, and
a plurality of memory cells each including a real magnetic tunnel junction (MTJ) layer in a first intersection region between one of the plurality of word lines and a corresponding one of the plurality of bit lines,
wherein the dummy cell region comprises
a plurality of dummy bit lines on the plurality of word lines and extending in the second direction such that at least one of a resistance or capacitance of the plurality of dummy bit lines is equal to the plurality of bit lines, and
a plurality of dummy memory cells each including a dummy MTJ layer in a second intersection region between one of the plurality of word lines and a corresponding one of the plurality of bit lines,
wherein the word line strap region comprises a plurality of word line strap patterns spaced apart from one another in the second direction,
wherein the dummy cell region is a reference wiring region configured to be used as a reference resistor in a read operation of the plurality of memory cells,
wherein the reference wiring region comprises reference wiring lines, the reference wiring lines including the plurality of dummy bit lines configured as the reference resistor, and
wherein the reference wiring lines are connected to cell via patterns included in the plurality of word line strap patterns in at least one of the cell center region and the cell edge region.

13. The variable resistance memory device of claim 12, wherein
the main cell region comprises a first main cell region and a second main cell region spaced apart from the first main cell region in the first direction,
the dummy cell region comprises a first dummy cell region adjacent to the first main cell region and a second dummy cell region spaced apart from the first dummy cell region in the first direction and adjacent to the second main cell region, and
the word line strap region is between the first dummy cell region and the second dummy cell region in the first direction.

14. The variable resistance memory device of claim 12, wherein the reference wiring lines comprise:
reference wiring patterns spaced apart from each other in the second direction, and
reference extension wiring patterns connected to the reference wiring patterns and extending in the first direction, and
wherein the reference extension wiring patterns are connected to the cell via patterns.

15. The variable resistance memory device of claim 14, wherein
the reference wiring patterns comprise lower reference wiring patterns under the dummy MTJ layer and upper reference wiring patterns on the dummy MTJ layer, and
the lower reference wiring patterns and the upper reference wiring patterns are connected to the cell via patterns.

16. The variable resistance memory device of claim 15, wherein the core/peripheral circuit region comprises core/peripheral via patterns connecting the lower reference wiring patterns to the upper reference wiring patterns.

17. A variable resistance memory device comprising:
a memory cell region; and
a core/peripheral circuit region at a perimeter of the memory cell region,
wherein the memory cell region comprises a main cell region and a reference wiring region,
wherein the main cell region and the reference wiring region comprise a plurality of word lines extending in a first direction and spaced apart from one another in a second direction perpendicular to the first direction,
wherein the main cell region further comprises
a plurality of bit lines on the plurality of word lines, extending in the second direction, and spaced apart from one another in the first direction, and
a plurality of memory cells each including a real magnetic tunnel junction (MTJ) layer in an intersection region between one of the plurality of word lines and a corresponding one of the plurality of bit lines,
wherein the reference wiring region comprises a reference wiring line, the reference wiring line including one of the plurality of bit lines configured as a reference resistor in a read operation of the plurality of memory cells, and
wherein the reference wiring line extends to the core/peripheral circuit region in the second direction.

18. The variable resistance memory device of claim 17, wherein
the reference wiring line comprises a lower reference wiring line under the real MTJ layer and an upper reference wiring line on the real MTJ layer, and
the lower reference wiring line and the upper reference wiring line are connected to core/peripheral via patterns.

19. The variable resistance memory device of claim 18, wherein
the core/peripheral via patterns comprise a first core/peripheral via pattern at one side of the memory cell region in the second direction and a second core/peripheral via pattern at another side of the memory cell region in the second direction, and
the lower reference wiring line and the upper reference wiring line are connected to the first core/peripheral via pattern and the second core/peripheral via pattern.

20. The variable resistance memory device of claim 17, wherein
the main cell region comprises a first main cell region and a second main cell region spaced apart from the first main cell region in the first direction, and
the reference wiring line is between the first main cell region and the second main cell region in the first direction.
